(19) United States
(12) Patent Application Publication
(10) Pub. No.: US 2025/0239298 A1
(43) Pub. Date: Jul. 24, 2025

(54) INTEGRATED CIRCUIT STRUCTURE AND METHOD FOR FABRICATING THE SAME

(71) Applicant: TAIWAN SEMICONDUCTOR MANUFACTURING COMPANY, LTD., Hsinchu (TW)

(72) Inventor: Jhon Jhy LIAW, Hsinchu County (TW)

(73) Assignee: TAIWAN SEMICONDUCTOR MANUFACTURING COMPANY, LTD., Hsinchu (TW)

(21) Appl. No.: 18/419,290

(22) Filed: Jan. 22, 2024

(51) Int. Cl. G11C 11/412; G11C 11/417; H01L 23/528; H10B 10/00

(52) U.S. Cl. CPC G11C 11/412; G11C 11/417; H01L 23/5286; H10B 10/12

(57) ABSTRACT

An integrated circuit (IC) structure includes a device layer, a first word line, a second word line, a first bit line, and a second bit line. The device layer includes first and second static random access memory (SRAM) cells arranged along a first direction in a top view. The first and second word lines extend along the first direction and respectively electrically coupled to the first and second SRAM cells. The first bit line is over a frontside of the device layer. The first bit line extends along a second direction and electrically coupled to the first and second SRAM cells. The second direction is different from the first direction in the top view. The second bit line is over a backside of the device layer. The second bit line extend along the second direction and electrically coupled to the first and second SRAM cells.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a circuit diagram of a static random access memory (SRAM) cell according to some embodiments of the present disclosure.

FIG. 1B illustrates a block diagram of an array of SRAM cells according to some embodiments of the present disclosure.

FIGS. 2-10B illustrate layouts and cross-sectional views of an integrated circuit structure at intermediate stages of fabrication process according to some embodiments of the present disclosure.

FIG. 11 is a cross-sectional view of an integrated circuit chip according to some embodiments of the present disclosure.

FIG. 12 illustrates a layout of an integrated circuit structure according to some embodiments of the present disclosure.

FIG. 13 illustrates a layout of an integrated circuit structure according to some embodiments of the present disclosure.

FIG. 14 illustrates a layout of an integrated circuit structure according to some embodiments of the present disclosure.

FIGS. 15A and 15B illustrate layouts of an integrated circuit structure according to some embodiments of the present disclosure.

FIG. 16A illustrates a block diagram of an integrated circuit structure according to some embodiments of the present disclosure.

FIG. 16B is a cross-sectional view of a tap structure of the integrated circuit chip of FIG. 16A.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

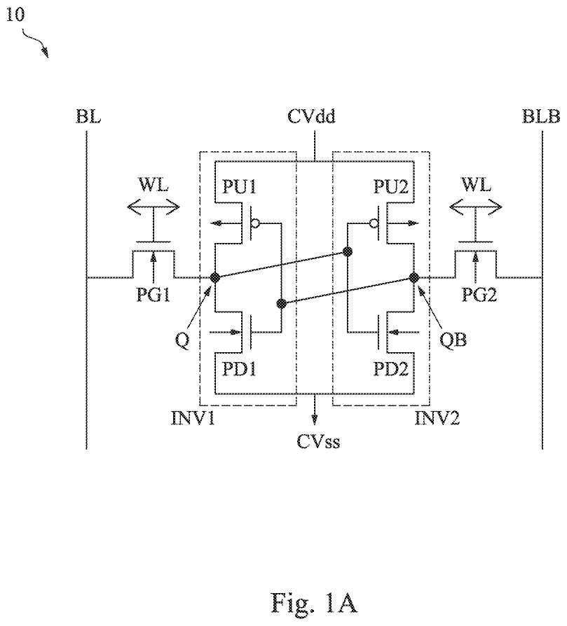

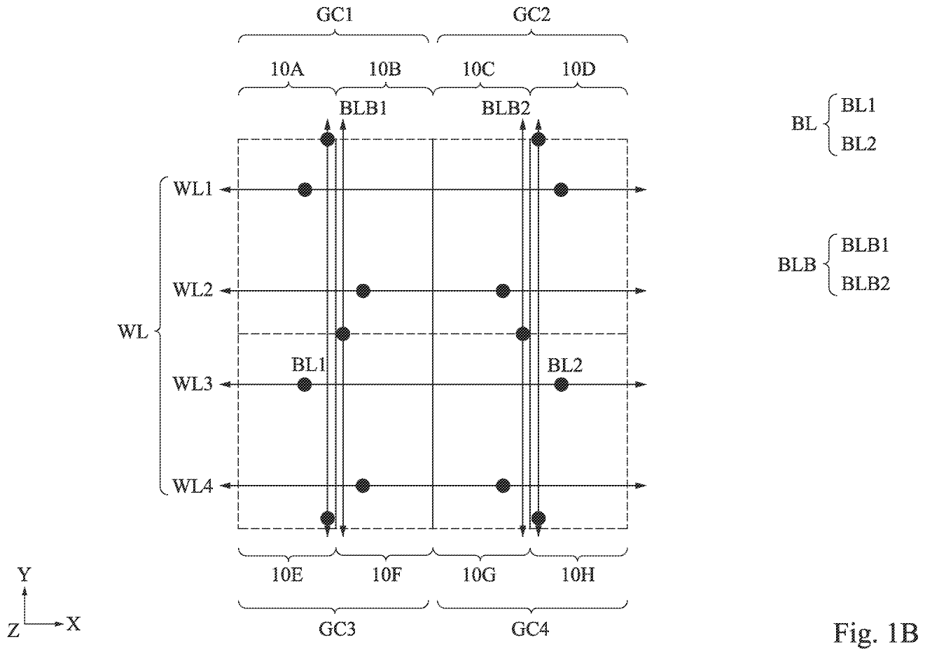

FIG. 1A is a circuit diagram of a static random access memory (SRAM) cell 10 according to some embodiments of the present disclosure. SRAM cell 10 includes pull-up transistors PU1 and PU2, which are p-type Metal-Oxide-Semiconductor (PMOS) transistors, and pull-down transistors PD1 and PD2 and pass-gate transistors PG1 and PG2, which are n-type Metal-Oxide-Semiconductor (NMOS) transistors. The gates of pass-gate transistors PG1 and PG2 are controlled by a word line WL that determines whether SRAM cell 10 is selected or not. A latch formed of pull-up transistors PU1 and PU2 and pull-down transistors PD1 and PD2 stores a bit, wherein the complementary values of the bit are stored in storage data nodes Q and QB. The stored bit can be written into, or read from, SRAM cell 10 through complementary bit lines including a bit line BL and a bit line bar BLB. SRAM cell 10 is powered through a positive power supply node CVdd that has a positive power supply voltage. SRAM cell 10 is also connected to a power supply voltage node CVss, which may be an electrical ground. Transistors PU1 and PD1 form a first inverter INV1. Transistors PU2 and PD2 form a second inverter INV2. The first and second inverters INV1 and INV2 are cross-latched. For example, the input of the first inverter INV1 (e.g., gates of the transistors PU1 and PD1) is connected to the output of the second inverter INV2 (e.g., drains of the transistors PU2 and PD2), and the output of the first inverter INV1 (e.g., drains of the transistors PU1 and PD1) is connected to the input of the second inverter INV2 (e.g., gates of the transistors PU2 and PD2). The input of the first inverter INV1 is also connected to the transistor PG2. The output of the first inverter is also connected to the transistor PG1.

The sources of pull-up transistors PU1 and PU2 are connected to positive power supply node CVdd. The sources of pull-down transistors PD1 and PD2 are connected to the power supply voltage node CVss. The gates of transistors PU1 and PD1 are connected to the drains of transistors PU2 and PD2, which form a connection node that is referred to as storage data node QB. The gates of transistors PU2 and PD2 are connected to the drains of transistors PU1 and PD1, which form a connection node is referred to as storage data node Q. A source/drain region of pass-gate transistor PG1 is connected to the bit line BL. A source/drain region of pass-gate transistor PG2 is connected to the bit line bar BLB.

FIG. 1B illustrates a block diagram of an array of SRAM cells according to some embodiments of the present disclosure. In some embodiments of the present disclosure, two adjacent SRAM cells in a same row may share a same bit line, a same bit line bar, and coupled to different word lines, respectively. For example, there are four groups GC1-GC4, and each of the groups GC1-GC4 may include two SRAM cells in the same row. For the group GC1, two adjacent SRAM cells 10A and 10B may share a bit line BL1 and a bit line bar BLB1, and be coupled to word lines WL1 and WL2, respectively. For group the GC2, two adjacent SRAM cells 10C and 10D share a bit line BL2 and a bit line bar BLB2, and coupled to the word lines WL1 and WL2, respectively. For the group GC3, two adjacent SRAM cells 10E and 10F may share the bit line BL1 and the bit line bar BLB1, and be coupled to word lines WL3 and WL4, respectively. For group the GC4, two adjacent SRAM cells 10G and 10H share the bit line BL2 and the bit line bar BLB2, and coupled to the word lines WL3 and WL4, respectively. For clear illustration, plural SRAM cells 10 are labelled as SRAM cells 10A-10H, plural bit lines BL are labelled as bit lines BL1 and BL2, plural bit line bars BLB are labelled as bit lines BLB1 and BLB2, and plural word lines WL are labelled as word lines WL1-WL4.

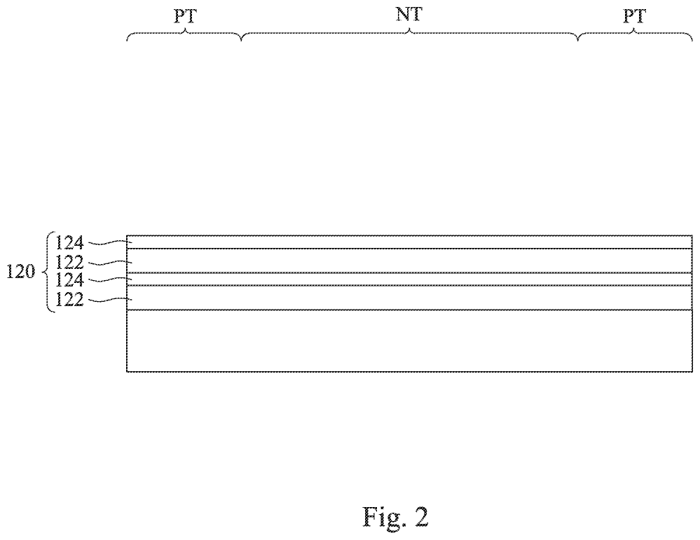

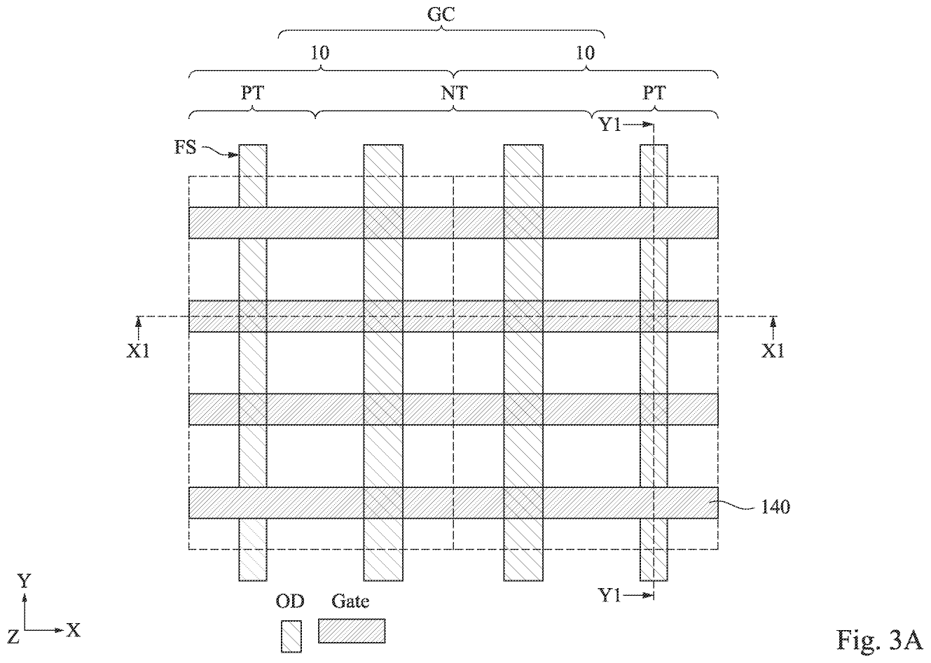

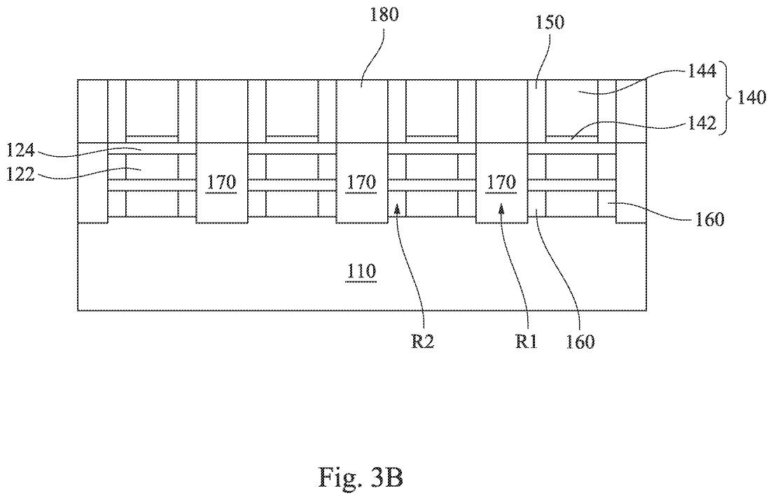

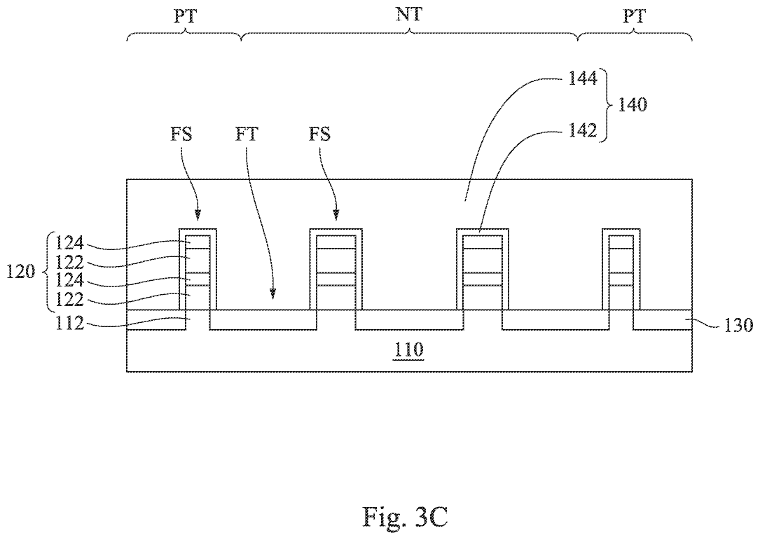

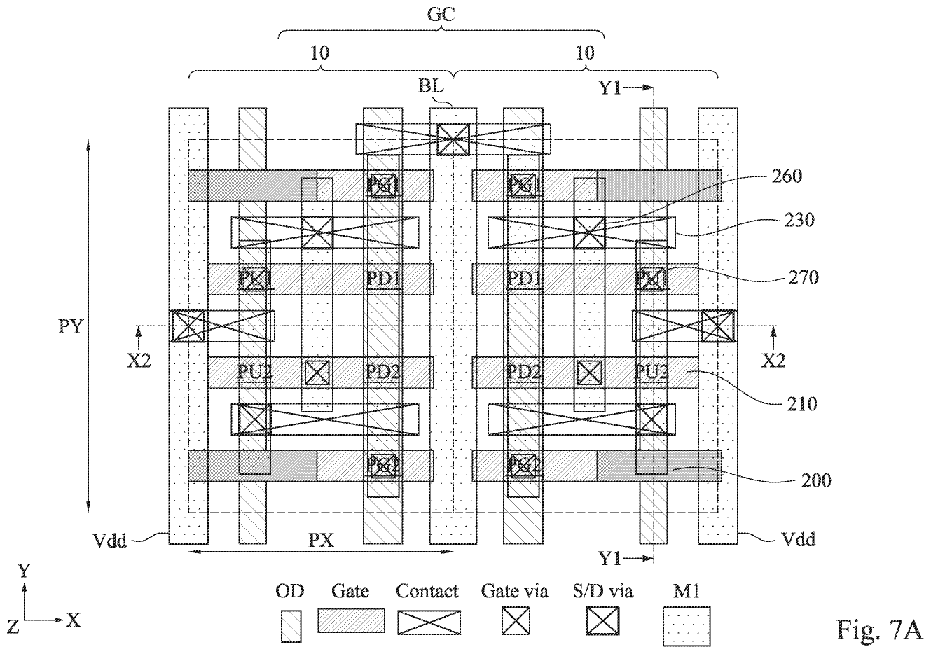

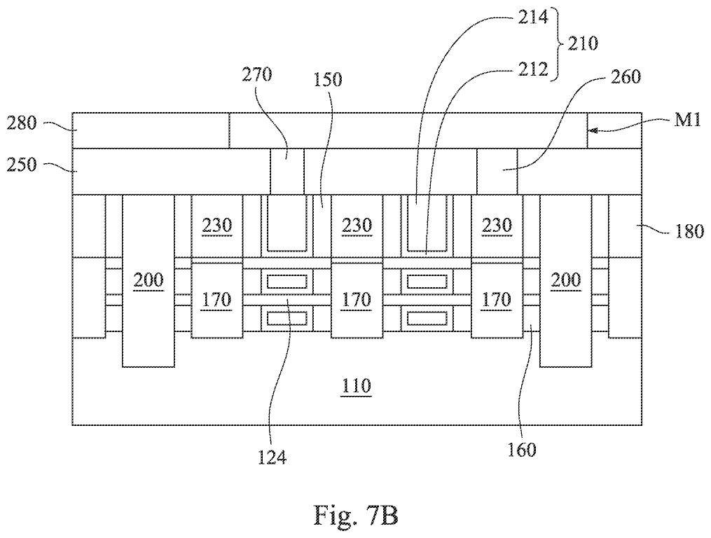

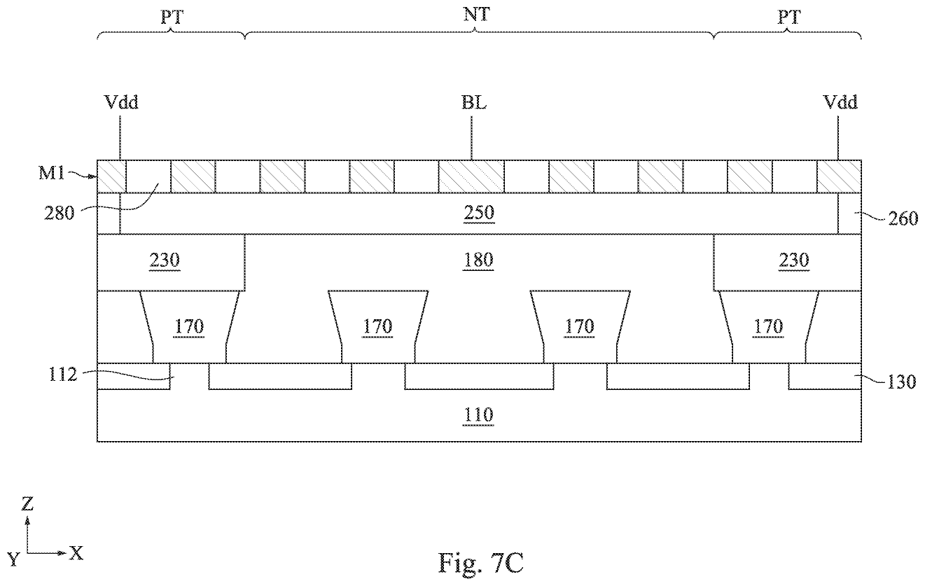

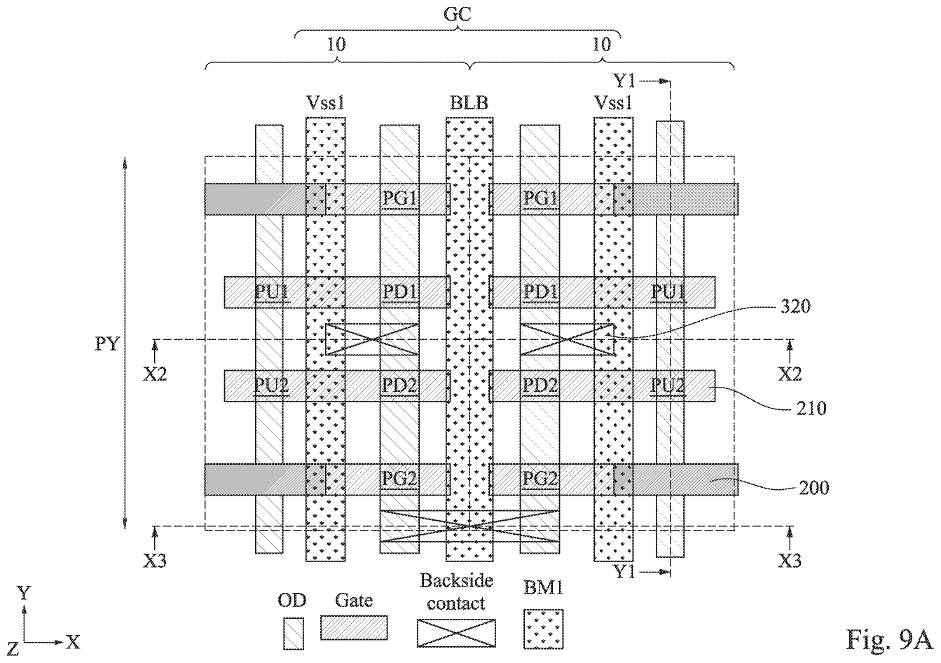

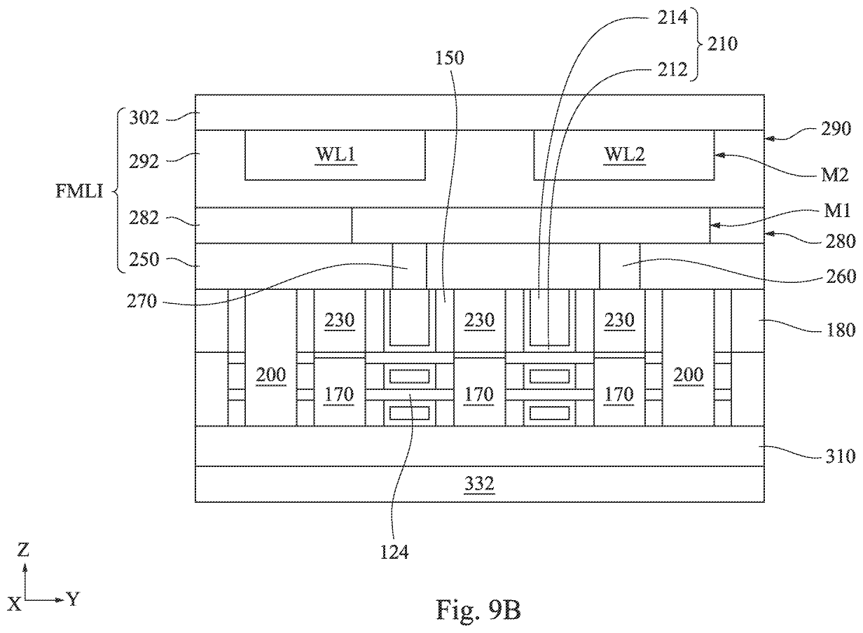

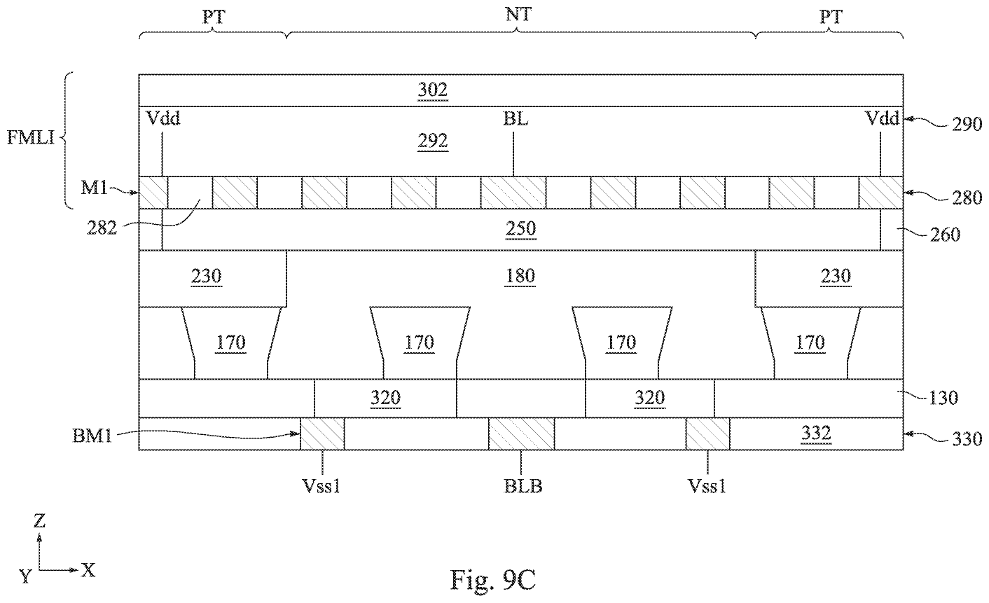

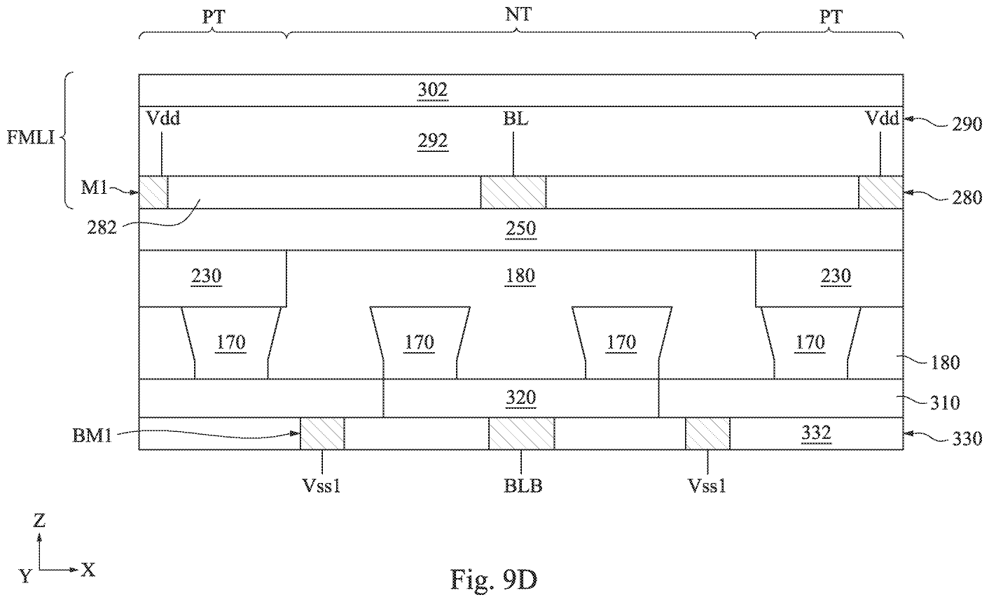

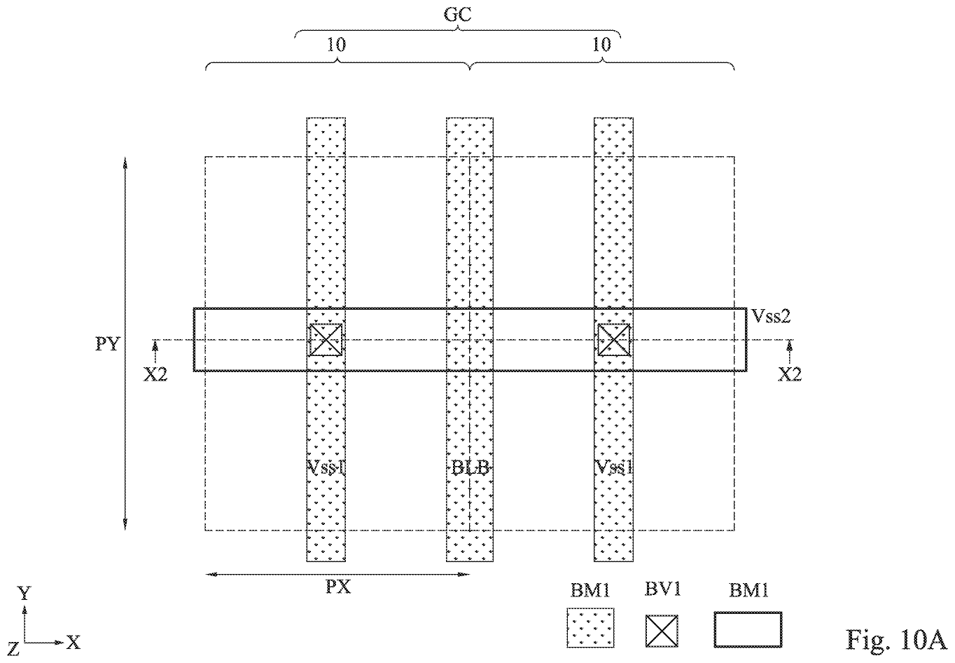

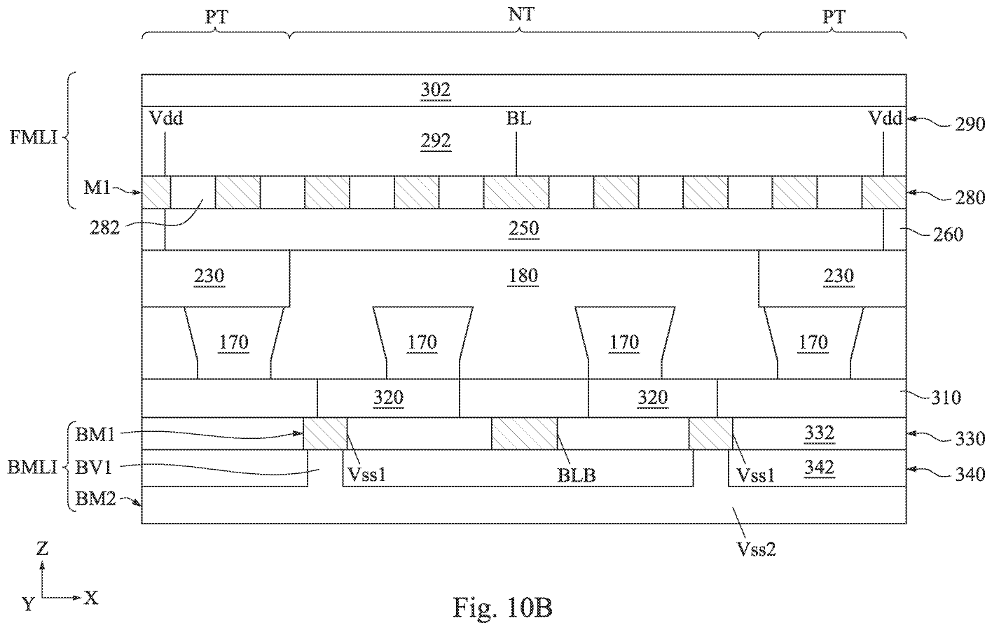

FIGS. 2-10B illustrate layouts and cross-sectional views of an integrated circuit structure at intermediate stages of fabrication process according to some embodiments of the present disclosure. FIGS. 3A, 4A, 5A, 6A, 7A, 8A, 9A, and 10A are layouts of the integrated circuit structure at the intermediate stages of fabrication process according to some embodiments of the present disclosure. FIGS. 3A, 4A, 5A, 6A, 7A, and 8A show front-side layouts, and FIGS. 9A and 10A show back-side layouts, while all the front-side layouts and back-side layouts are illustrated as being viewed from top/front side. In the layouts of FIGS. 3A, 4A, 5A, 6A, 7A, 8A, 9A, and 10A, boundaries of standard cells 10 are shown, in which the standard cells 10 corresponds to a static random access memory (SRAM). FIGS. 3B, 4B, 6B, 7B, 8B, and 9B illustrate cross-sectional views taken along line Y1-Y1 in FIGS. 3A, 4A, 6A, 7A, 8A, and 9A, respectively. FIGS. 3C, 4C, and 5B illustrate cross-sectional views taken along line X1-X1 in FIGS. 3A, 4A, and 5A respectively. FIGS. 7C, 9C, and 10B illustrate cross-sectional views taken along line X2-X2 in FIGS. 7A, 9A, and 10B, respectively. FIG. 9D illustrates a cross-sectional view taken along line X3-X3 in FIG. 9A. As with the other method embodiments and exemplary devices discussed herein, it is understood that parts of the integrated circuit structure may be fabricated by a CMOS technology process flow, and thus some processes are only briefly described herein. Further, the exemplary integrated circuit structure may include various other devices and features, such as other types of devices such as additional transistors, bipolar junction transistors, resistors, capacitors, inductors, diodes, fuses, and/or other logic circuits, etc., but is simplified for a better understanding of the concepts of the present disclosure. In some embodiments, the exemplary integrated circuit structure includes a plurality of semiconductor devices (e.g., transistors), including PFETs, NFETs, etc., which may be interconnected.

FIG. 2 shows an initial structure. The initial structure includes a substrate 110. In some embodiments, the substrate 110 may include silicon (Si). Alternatively, the substrate 110 may include germanium (Ge), silicon germanium (SiGe), a III-V material (e.g., GaAs, GaP, GaAsP, AlInAs, AlGaAs, GalnAs, InAs, GalnP, InP, InSb, and/or GaInAsP; or a combination thereof) or other appropriate semiconductor materials. In some embodiments, the substrate 110 may include a semiconductor-on-insulator (SOI) structure. For example, the substrate 110 may include a bulk semiconductor substrate, a buried dielectric layer over the bulk substrate, and a semiconductor layer over the buried dielectric layer. The substrate 110 may include a region NT where n-type devices (e.g., NMOSFET) are to be formed and a region PT where p-type devices (e.g., PMOSFET) are to be formed.

An epitaxial stack 120 is formed over the substrate 110. The epitaxial stack 120 includes epitaxial layers 122 of a first composition interposed by epitaxial layers 124 of a second composition. The first and second compositions can be different. In some embodiments, the epitaxial layers 122 are SiGe and the epitaxial layers 124 are silicon (Si). However, other embodiments are possible including those that provide for a first composition and a second composition having different oxidation rates and/or etch selectivity. In some embodiments, the epitaxial layers 122 include SiGe and where the epitaxial layers 124 include Si, the Si oxidation rate of the epitaxial layers 124 is less than the SiGe oxidation rate of the epitaxial layers 122.

The epitaxial layers 124 or portions thereof may form nanosheet channel(s) of the multi-gate transistor. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. The use of the epitaxial layers 124 to define a channel or channels of a device is further discussed below. It is noted that two layers of the epitaxial layers 122 and two layers of the epitaxial layers 124 are alternately arranged as illustrated in FIG. 2. It can be appreciated that any number of epitaxial layers can be formed in the epitaxial stack 120; the number of layers depending on the desired number of channels regions for the transistor. In some embodiments, the number of epitaxial layers 124 is between 2 and 10.

In some embodiments, the epitaxial layers 122 may be substantially uniform in thickness, and the epitaxial layers 124 of the stack are substantially uniform in thickness. As described in more detail below, the epitaxial layers 124 may serve as channel region(s) for a subsequently-formed multi-gate device and the thickness is chosen based on device performance considerations. The epitaxial layers 122 in channel regions(s) may eventually be removed and serve to define a vertical distance between adjacent channel region(s) for a subsequently-formed multi-gate device and the thickness is chosen based on device performance considerations. Accordingly, the epitaxial layers 122 may also be referred to as sacrificial layers, and epitaxial layers 124 may also be referred to as channel layers. The structure of said devices are formed by either FinFET transistors, or GAA transistors, or CFET (vertical stacked N/P MOSFETs) or SOI planar transistors, or SOI fin-structure (3D) transistors, or SOI GAA transistors, or combination. The channel region of the GAA device can be nana-wire, or nano-sheet, or fork-sheet and have vertically stacked multiple channels (sheets or wires), or combination.

By way of example, epitaxial growth of the layers of the stack 120 may be performed by a molecular beam epitaxy (MBE) process, a metalorganic chemical vapor deposition (MOCVD) process, and/or other suitable epitaxial growth processes. In some embodiments, the epitaxially grown layers such as, the epitaxial layers 124 include the same material as the substrate 110. In some embodiments, the epitaxially grown layers 122 and 124 include a different material than the substrate 110. As stated above, in at least some examples, the epitaxial layers 122 include an epitaxially grown silicon germanium (SiGe) layer and the epitaxial layers 124 include an epitaxially grown silicon (Si) layer. Alternatively, in some embodiments, either of the epitaxial layers 122 and 124 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GalnP, and/or GaInAsP, or combinations thereof. As discussed, the materials of the epitaxial layers 122 and 124 may be chosen based on providing differing oxidation and/or etching selectivity properties. In some embodiments, the epitaxial layers 122 and 124 are substantially dopant-free (i.e., having an extrinsic dopant concentration from about 0 cm⁻³ to about 1×10¹⁸ cm⁻³), where for example, no intentional doping is performed during the epitaxial growth process.

Reference is made to FIGS. 2A and 2B. The epitaxial stack 120 and the substrate 110 are patterned, thereby forming plural fins FS. The fins FS may extend along direction X. The patterning may include suitable lithography process and etching processes. The lithography process (e.g., photolithography or e-beam lithography) may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., reactive ion etching), wet etching, and/or other etching methods. In some embodiments, masks are formed over the epitaxial stack 120 by the photolithography process. The masks are used to protect regions of the substrate 110 and the epitaxial stack 120, while etching processes form trenches FT in unprotected regions through the epitaxial stack 120 and into the substrate 110, thereby leaving the plurality of extending fins FS.

In some alternative embodiments, the fins FS may be fabricated using suitable processes including double-patterning or multi-patterning processes. The double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins FS by etching initial epitaxial stack 120. The etching process can include dry etching, wet etching, reactive ion etching (RIE), and/or other suitable processes.

Numerous other embodiments of methods to form the fins on the substrate may also be used including, for example, defining the fin region (e.g., by mask or isolation regions) and epitaxially growing the epitaxial stack 120 in the form of the fins FS. In various embodiments, each of the fins FS includes a base portion 112 patterned from the semiconductor substrate 110 and portions of each of the epitaxial layers 122 and 124 of the epitaxial stack 120.

Isolation structures 130 are formed in the trenches FT between the fins FS. The isolation structures 130 may be referred to as shallow trench isolation (STI) structures. By way of example and not limitation, a dielectric layer is first deposited over the substrate 110, filling the trenches FT with the dielectric material. In some embodiments, the dielectric layer may include silicon oxide, silicon nitride, silicon oxynitride, fluorine-doped silicate glass (FSG), a low-k dielectric, combinations thereof, and/or other suitable materials. In various examples, the dielectric layer may be deposited by a CVD process, a sub-atmospheric CVD (SACVD) process, a flowable CVD process, an ALD process, a physical vapor deposition (PVD) process, and/or other suitable processes. In some embodiments, the dielectric layer may include a multi-layer structure, for example, having one or more liner layers. In some embodiments, after deposition of the dielectric layer, the deposited dielectric material is thinned and planarized, for example by a chemical mechanical polishing (CMP) process.

In the layouts, regions between the isolation structures 130 are indicated as oxide-defined (OD) regions, which correspond to the fins FS. The isolation (or STI) structures 130 are recessed in an etch back process, such that the oxide-defined (OD) regions (e.g., fins FS) has exposed sidewall extending above the isolation structure 130. In some embodiments, the recessing process may include a dry etching process, a wet etching process, and/or a combination thereof. In some embodiments, a recessing depth is controlled (e.g., by controlling an etching time) so as to result in a target height of the exposed upper portion of the fins FS. The target height may expose sidewalls of the OD regions (e.g., fins FS). In the illustrated embodiments, the target height exposes each of the epitaxial layers 122 and 124 of the epitaxial stack 120 in the fins FS.

A dummy gate dielectric layer 142 is then conformally deposited in the trenches FT and over the isolation structures 130. In some embodiments, the dummy gate dielectric layer 142 may include SiO₂, silicon nitride, a high-k dielectric material and/or other suitable material. In various examples, the dummy gate dielectric layer 142 may be deposited by a CVD process, a subatmospheric CVD (SACVD) process, a flowable CVD process, an ALD process, a PVD process, or other suitable process. By way of example, the dummy gate dielectric layer 142 may be used to prevent damages to the fins FS by subsequent processes (e.g., subsequent formation of the dummy gate structures).

Dummy gate structures 140 are formed in accordance with some embodiments of the present disclosure. The dummy gate structures 140 may extend along the direction Y intersecting the direction X that the fins FS extend along. For example, the direction Y is orthogonal to the direction X. In some embodiments, the dummy gate structures 140 each include the dummy gate dielectric layer 142 and a dummy gate electrode layer 144. In some embodiments, the dummy gate structures 140 are formed by various process steps such as layer deposition, patterning, etching, as well as other suitable processing steps. Exemplary layer deposition processes include CVD (including both low-pressure CVD and plasma-enhanced CVD), PVD, ALD, thermal oxidation, e-beam evaporation, or other suitable deposition techniques, or combinations thereof. In forming the gate structures for example, the patterning process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods. In some embodiments, the dummy gate electrode layer 144 may include polycrystalline silicon (polysilicon). In some embodiments, after patterning the dummy gate electrode layer 144, exposed portions of the dummy gate dielectric layer 142 not covered under the patterned dummy gate electrode layer 144 are removed from source/drain regions of the fins FS. The etch process may include a wet etch, a dry etch, and/or a combination thereof.

In some embodiments, gate spacers 150 are formed on sidewalls of the dummy gate structures 140. The gate spacers 150 may include a dielectric material such as SiO₂, Si₃N₄, carbon doped oxide, nitrogen doped oxide, porous oxide, or the combination thereof. The gate spacers 150 may include multiple dielectric materials. In some embodiments, the gate spacers 150 may further include air gaps. In some embodiments of formation of the gate spacers 150, a spacer material layer is first deposited over the substrate 110. The spacer material layer may be a conformal layer that is subsequently etched to form gate sidewall spacers on sidewalls of the dummy gate structures 140. In the illustrated embodiments, a spacer material layer is disposed conformally on top and sidewalls of the dummy gate structures 140. By way of example, the spacer material layer may be formed by depositing a dielectric material over the gate structures 140 using processes such as, CVD process, a subatmospheric CVD (SACVD) process, a flowable CVD process, an ALD process, a PVD process, or other suitable process. An anisotropic etching process is then performed on the deposited spacer material layer to expose portions of the fins FS not covered by the dummy gate structures 140 (e.g., in source/drain regions of the fins FS). Portions of the spacer material layer directly above the dummy gate structures 140 may be completely removed by this anisotropic etching process. Portions of the spacer material layer on sidewalls of the dummy gate structures 140 may remain, forming gate sidewall spacers, which are denoted as the gate spacers 150, for the sake of simplicity. The gate spacers 150 serve to isolate metal gates from source/drain contacts formed in subsequent processing.

Exposed portions of the semiconductor fins FS that extend laterally beyond the gate spacers 150 (e.g., in source/drain regions S/D of the fins FS) are etched by using, for example, an anisotropic etching process that uses the dummy gate structures 140 and the gate spacers 150 as an etch mask, resulting in recesses R1 into the semiconductor fins FS and between corresponding dummy gate structures 140. In some embodiments, the recesses R1 extends through the channel regions to the substrate 110 for exposing the sacrificial layers 122 and channel layers 124.

The sacrificial layers 122 may be laterally recessed by using suitable etch techniques, resulting in lateral recesses R2 each vertically between corresponding channel layers 124. This step may be performed by using a selective etching process. By way of example and not limitation, the sacrificial layers 122 are SiGe and the channel layers 124 are silicon allowing for the selective etching of the sacrificial layers 122. In some embodiments, the selective wet etching includes an APM etch (e.g., ammonia hydroxide-hydrogen peroxide-water mixture) that etches SiGe at a faster etch rate than it etches Si. In some embodiments, the selective etching includes SiGe oxidation followed by a SiGeOₓ removal. For example, the oxidation may be provided by O₃ clean and then SiGeOₓ removed by an etchant such as NH₄OH that selectively etches SiGeOₓ at a faster etch rate than it etches Si. Moreover, because oxidation rate of Si is much lower than oxidation rate of SiGe, the channel layers 124 remain substantially intact during laterally recessing the sacrificial layers 122. As a result, the channel layers 124 laterally extend past opposite end surfaces of the sacrificial layers 122.

After the sacrificial layers 122 have been laterally recessed, inner spacers 160 are formed in the recesses R2 left by the lateral etching of the sacrificial layers 122. For example, the inner spacers 160 includes a suitable dielectric material, such as SiO₂, Si₃N₄, SION, SiOC, SiOCN, the like, or the combination thereof. Formation of the inner spacers 160 may include depositing an inner spacer material layer is formed to fill the recesses R2. The inner spacer material layer may be deposited by a suitable deposition method, such as ALD. After the deposition of the inner spacer material layer, an anisotropic etching process may be performed to trim the deposited inner spacer material, such that only portions of the deposited inner spacer material that fill the recesses left by the lateral etching of the sacrificial layers 122 are left. After the trimming process, the remaining portions of the deposited inner spacer material are denoted as inner spacers 160. The inner spacers 160 serve to isolate metal gates from source/drain epitaxial structures formed in subsequent processing.

Source/drain epitaxial structures 170 are formed in the recesses R1 in the fins FS. The source/drain epitaxial structures 170 may be formed by performing an epitaxial growth process that provides an epitaxial material on the fins FS. Suitable epitaxial processes include CVD deposition techniques (e.g., vapor-phase epitaxy (VPE) and/or ultra-high vacuum CVD (UHV-CVD)), molecular beam epitaxy, and/or other suitable processes. The epitaxial growth process may use gaseous and/or liquid precursors, which interact with the composition of semiconductor materials of the fins FS and the channel layers 124.

The source/drain epitaxial structures 170 may be in-situ doped during the epitaxial process by introducing doping species including: p-type dopants, such as boron; n-type dopants, such as phosphorus or arsenic; and/or other suitable dopants including combinations thereof. If the source/drain epitaxial structures 170 are not in-situ doped, an implantation process (i.e., a junction implant process) is performed to dope the source/drain epitaxial structures 170. In some exemplary embodiments, the source/drain epitaxial structures 170 in an NFET device include SiP, SiC, SiPC, SiAs, Si, or combination thereof. The n-type doping concentration of the source/drain epitaxial structures 170 (e.g., phosphorus, arsenic, or both) in the NFET device may be in a range from about 2E19/cm³ to about 3E21/cm³. In some exemplary embodiments, the source/drain epitaxial structures 170 in a PFET device include SiGe doped with boron, or SiGeC doped with boron, Ge doped with boron, Si doped with boron, or combination. The p-type doping concentration of the source/drain epitaxial structures 170 (e.g., boron) in the PFET device may be in a range from about 1E19/cm³ to about 6E20/cm³.

A dielectric material 180 is formed over the substrate 110 and filling the space between the dummy gate structures 140. In some embodiments, the dielectric material 180 includes a contact etch stop layer (CESL) and an interlayer dielectric (ILD) layer formed in sequence. In some examples, the CESL includes a silicon nitride layer, silicon oxide layer, a silicon oxynitride layer, and/or other suitable materials having a different etch selectivity than the ILD layer. The CESL may be formed by plasma-enhanced chemical vapor deposition (PECVD) process and/or other suitable deposition or oxidation processes. The ILD layer is then deposited over the CESL. In some embodiments, the ILD layer includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL. The ILD layer may be deposited by a PECVD process or other suitable deposition technique. After depositing the dielectric material 180, a planarization process may be performed to remove excessive materials of the dielectric material 180. For example, a planarization process includes a chemical mechanical planarization (CMP) process which removes portions of the dielectric material 180 overlying the dummy gate structures 140 and planarizes a top surface of the integrated circuit structure.

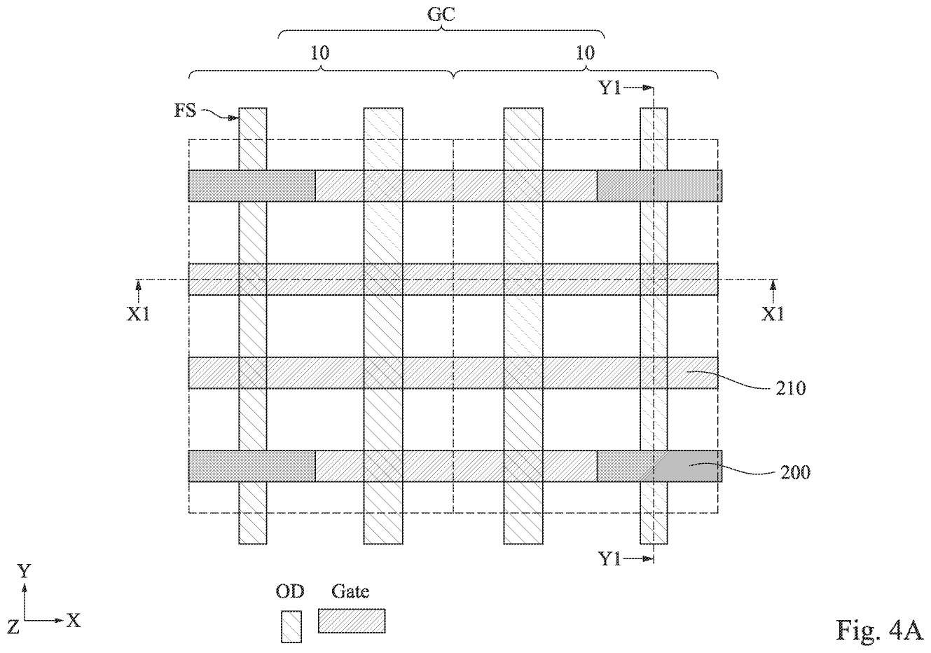

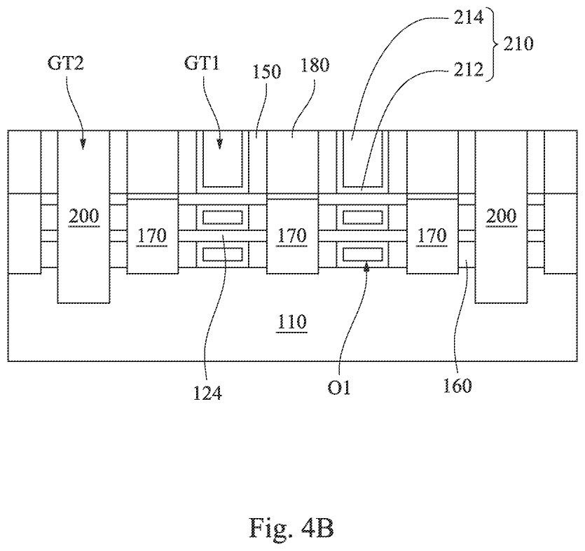

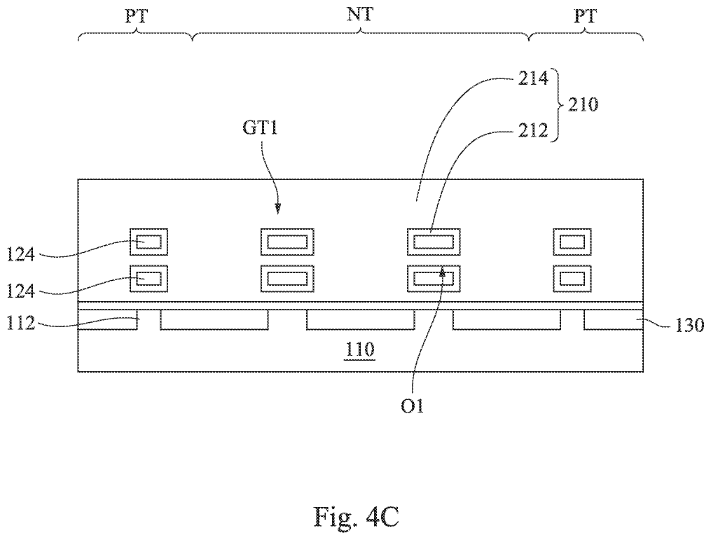

Reference is made to FIGS. 4A-4C. Some dummy gate structures 140 (referring to FIGS. 3A-3C) are replaced with metal gate structures 210. The metal gate replacement process may include removing a first group of the dummy gate structures 140 (referring to FIGS. 3A-3C), and removing the sacrificial layers 122 (referring to FIGS. 3B and 3C) therebelow. The removals form gate trenches GT1 between the gate spacers 150 and openings/spaces O1 between neighboring channel layers 124. Replacement gate structures 210 are respectively formed in the gate trenches GT1 and openings/spaces O1 to surround each of the channel layers 124 suspended in the gate trenches GT1.

In the illustrated embodiments, the dummy gate structures 140 (referring to FIGS. 3A-3C) are removed by using a selective etching process (e.g., selective dry etching, selective wet etching, or a combination thereof) that etches the materials in dummy gate structures 140 (referring to FIGS. 3A-3C) at a faster etch rate than it etches other materials (e.g., gate spacers 150 and the dielectric material 180), thus resulting in gate trenches GT1 between corresponding gate spacers 150, with the top surface and sidewalls of the fins FS exposed in the gate trenches GT1. Subsequently, the sacrificial layers 122 in the gate trenches GT1 are etched by using another selective etching process that etches the sacrificial layers 122 at a faster etch rate than it etches the channel layers 124, thus forming openings/spaces O1 between neighboring channel layers 124. In this way, the channel layers 124 become nanosheets suspended over the substrate 110 and between the source/drain epitaxial structures 170. This step is also called a channel release process. In some embodiments, the nanosheets 124 can be interchangeably referred to as nanowires, nanoslabs and nanorings, depending on their geometry. For example, in some other embodiments the channel layers 124 may be trimmed to have a substantial rounded shape (i.e., cylindrical) due to the selective etching process for completely removing the sacrificial layers 122 (referring to FIGS. 3A-3C). In that case, the resultant channel layers 124 can be called nanowires.

In some embodiments, the sacrificial layers 122 (referring to FIGS. 3A-3C) are removed by using a selective wet etching process. In some embodiments, the sacrificial layers 122 (referring to FIGS. 3A-3C) are SiGe and the channel layers 124 are silicon allowing for the selective removal of the sacrificial layers 122. In some embodiments, the selective wet etching includes an APM etch (e.g., ammonia hydroxide-hydrogen peroxide-water mixture). In some embodiments, the selective removal includes SiGe oxidation followed by a SiGeOₓ removal. For example, the oxidation may be provided by O₃ clean and then SiGeOₓ removed by an etchant such as NH₄OH that selectively etches SiGeOₓ at a faster etch rate than it etches Si. Moreover, because oxidation rate of Si is much lower (sometimes 30 times lower) than oxidation rate of SiGe, the channel layers 124 may remain substantially intact during the channel release process. In some embodiments, both the channel release step and the previous step of laterally recessing sacrificial layers use a selective etching process that etches SiGe at a faster etch rate than etching Si, and therefore these two steps may use the same etchant chemistry in some embodiments. In this case, the etching time/duration of channel release step is longer than the etching time/duration of the previous step of laterally recessing sacrificial layers, so as to completely remove the sacrificial SiGe layers.

The gate structures 210 may be final gates of GAA FETs. The final gate structure may be a high-k/metal gate stack, however other compositions are possible. In some embodiments, each of the gate structures 210 forms the gate associated with the multi-channels provided by the plurality of nanosheets 124. For example, high-k/metal gate structures 210 are formed within the openings O1 provided by the release of nanosheets 124. In various embodiments, the high-k/metal gate structure 210 includes a gate dielectric layer 212 around the nanosheets 124 and a gate metal layer 214 formed around the gate dielectric layer 212 and filling a remainder of gate trenches GT1. Formation of the high-k/metal gate structures 210 may include one or more deposition processes to form various gate materials, followed by a CMP processes to remove excessive gate materials.

In some embodiments, the gate dielectric layer 212 includes an interfacial layer formed around the nanosheets 124 and a high-k gate dielectric layer formed around the interfacial layer. The interfacial layer may be silicon oxide formed on exposed surfaces of semiconductor materials in the gate trenches GT1 by using, for example, thermal oxidation, chemical oxidation, wet oxidation or the like. As a result, surface portions of the nanosheets 124 and the substrate 110 exposed in the gate trenches GT1 are oxidized into silicon oxide to form interfacial layer. In some embodiments, the high-k gate dielectric layer includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof.

In some embodiments, the gate metal layer 214 includes one or more metal layers. For example, the gate metal layer 214 may include one or more work function metal layers stacked one over another and a fill metal filling up a remainder of gate trenches GT1. The one or more work function metal layers in the gate metal layer 214 provide a suitable work function for the high-k/metal gate structures 210. The work function metal layers may include TiN, TaN, TiAl, TiAlN, TaAl, TaAlN, TaAlC, TaCN, WNC, Co, Ni, Pt, W, or combination thereof. NMOSFET and PMOSFET may include the same work function material, or different work function materials. For example, n-type work function metals in the region NT for NMOSFET may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. P-type work function metal in the region PT for PMOSFET may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal in the gate metal layer 214 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials. One for more lithography and patterning processes may be performed for forming the work-function metals for NMOSFET and forming the work-function metals for PMOSFET.

In some embodiments, before or after replacing the first group of the dummy gate structures 140 with the metal gate structures 210, a second group of dummy gate structures 140 is replaced with isolation features 200, which may also be referred to as dielectric gates. The dielectric gate replacement process may include removing the second group of the dummy gate structures 140 (referring to FIGS. 3A-3C), and removing the sacrificial layers 122 and channel layers 124 (referring to FIGS. 3B and 3C) therebelow. The removals form gate trenches GT2 between the gate spacers 150 and between the inner spacers 160. The isolation features 200 are respectively formed in the gate trenches GT2. In some embodiments, the isolation features 200 includes suitable dielectric materials, such as silicon oxide (SiO₂), a silicon nitride (SiN), a silicon carbide (SiC), a silicon oxynitride (SiON), other suitable materials, and/or combinations thereof. The dielectric material may be deposited by a PECVD process or other suitable deposition technique. After depositing the dielectric material, a planarization process may be performed to remove excessive materials of the dielectric material. For example, a planarization process includes a chemical mechanical planarization (CMP) process which removes portions of the dielectric material 180 overlying gate structures 140/210 and planarizes a top surface of the integrated circuit structure.

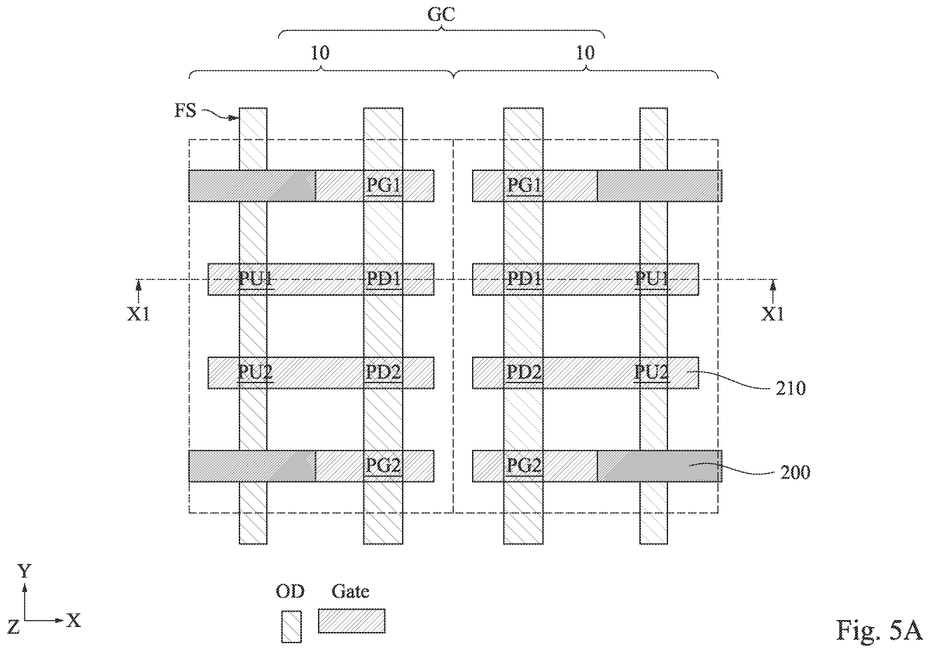

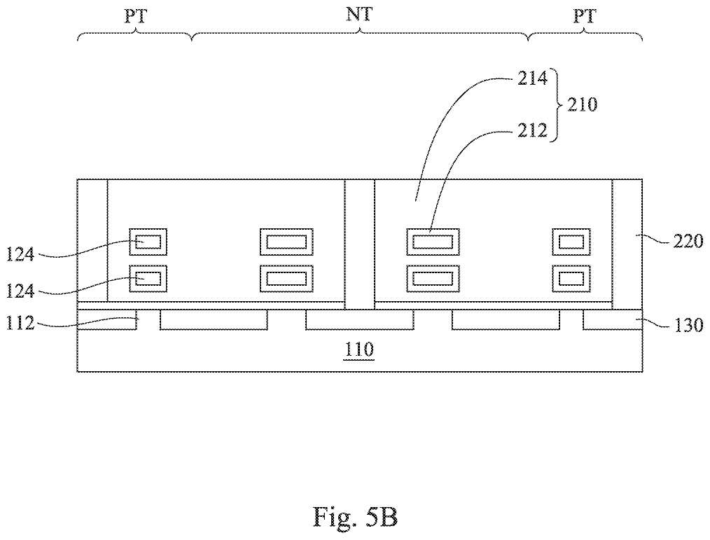

Reference is made to FIGS. 5A and 5B. A gate end dielectric 220 may either be disposed between gate structures 210, at an end of a gate structure 210 after a gate cut process, between isolation features (or dielectric gates) 200, at an end of an isolation feature (or dielectric gate) 200 after a gate cut process. In some embodiments, the gate end dielectric 220 may be referred to as dielectric plugs. The gate end dielectric layer 220 may include suitable dielectric materials, such as oxide, Si₃N₄, other nitride-base dielectric, carbon-base dielectric, high k material (e.g., having a k value equal to or greater than 9), or other suitable dielectric material. Formation of the gate end dielectric 220 may include etching away portions of the metal gate structures 210 and the isolation features (or the dielectric gates) 200 to expose underlying dielectric materials (e.g., the isolation features 130), and depositing the suitable gate end dielectric materials over the underlying dielectric materials (e.g., the isolation features 130). A CMP process may be performed to remove excess portions of the gate end dielectric materials, leaving the remaining portions forming the gate end dielectric 220. Through the configuration, the gate end dielectric 220 and the isolation features (or the dielectric gates) 200 are located at boundaries of the cells 10 for isolation purposes.

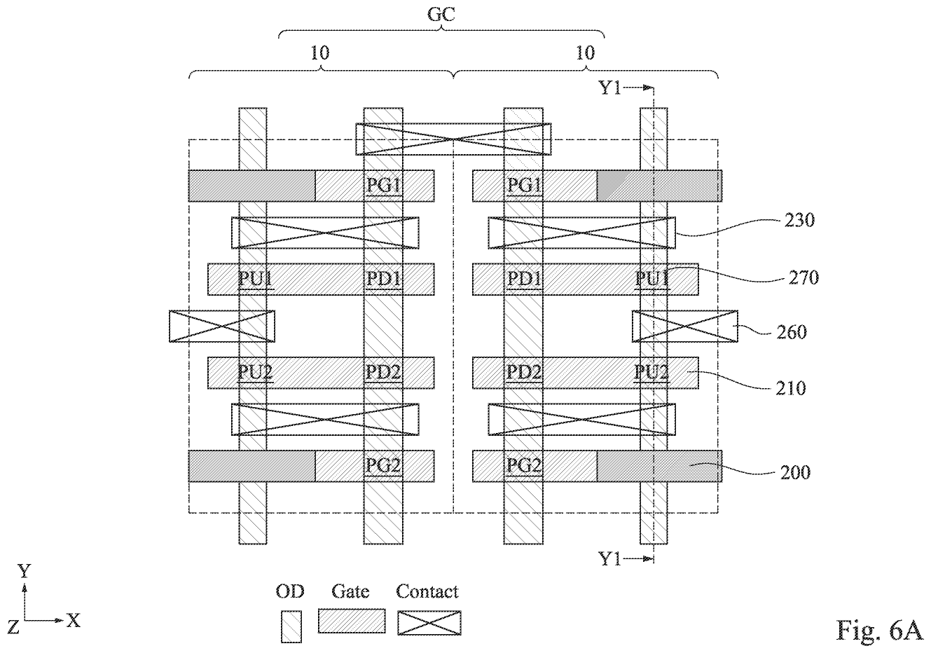

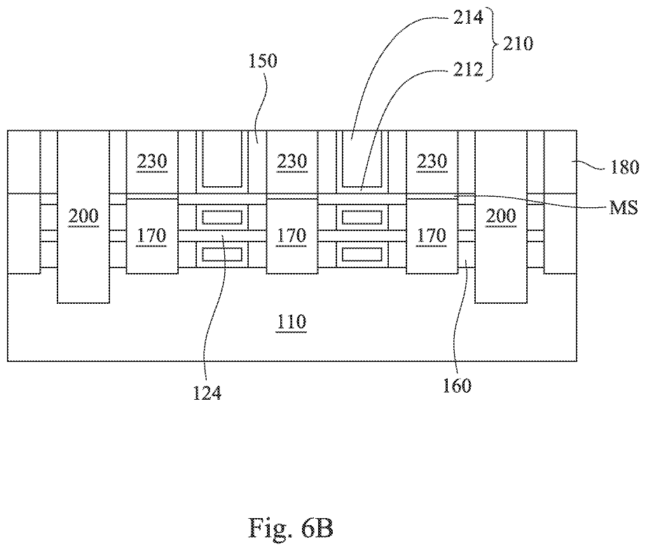

Reference is made to FIGS. 6A and 6B. Source/drain contacts 230 are formed over the source/drain epitaxial structures 170. In some embodiments, the formation of the source/drain contacts 230 includes etching source/drain contact openings through the dielectric material 180 to expose top surfaces of the source/drain epitaxial structures 170, and depositing one or more metal materials into the source/drain contact openings. The metal materials may include W, Ru, Co, Cu, Ti, TiN, Ta, TaN, Mo, Ni, Pt, Ir, Rh, the like or combinations thereof. The metal materials are deposited to fill the source/drain contact openings by using suitable deposition techniques (e.g., CVD, PVD, ALD, the like or combinations thereof). Subsequently, a CMP process can be performed to remove excess metal materials outside the source/drain contact openings, while leaving metal materials in the source/drain contact openings to serve as the source/drain contacts 230. The source/drain contacts 230 may include a single metal material or multiple metal material layers. The source/drain contacts 230 may be isolated from the gate structure 210 by the gate spacers 150 and the inner spacer 160. In some embodiments, from the layout top view as shown in FIG. 6A, the source/drain contacts 230 may be elongated. For example, and the dimension of a longer side of the source/drain contacts 230 is greater than the dimension of a short side of the source/drain contacts 230.

In some embodiments, prior to depositing the metal materials of the source/drain contacts 230, metal silicide regions MS may be formed on exposed top surfaces of the source/drain epitaxial structures 170 by using a silicidation process. Silicidation may be formed by blanket depositing a metal layer over the exposed source/drain epitaxial structures 170, annealing the metal layer such that the metal layer reacts with silicon (and germanium if present) in the source/drain epitaxial structures 170 to form the metal silicide regions MS, and thereafter removing the non-reacted metal layer. In some embodiments, the metal layer used in the silicidation process includes nickel, cobalt, titanium, tantalum, platinum, tungsten, other noble metals, other refractory metals, rare earth metals or their alloys. Thus, metal silicide regions MS may be between the source/drain contacts 230 and the source/drain epitaxial structure 170.

Reference is made to FIGS. 7A-7C. Source drain vias 260 and gate vias 270 are formed over the source/drain contacts 230 and the high-k/metal gate structures 210, respectively. Formation of the source drain vias 260 and/or the gate vias 270 may include etching an opening in a dielectric layer 250 deposited over the source/drain contacts 230 and the high-k/metal gate structures 210, etching one openings in the dielectric layer 250, and depositing conductive materials into the openings in the dielectric layer 250. A CMP process may be performed to remove excess portions of the conductive materials outside the openings in the dielectric layer 250.

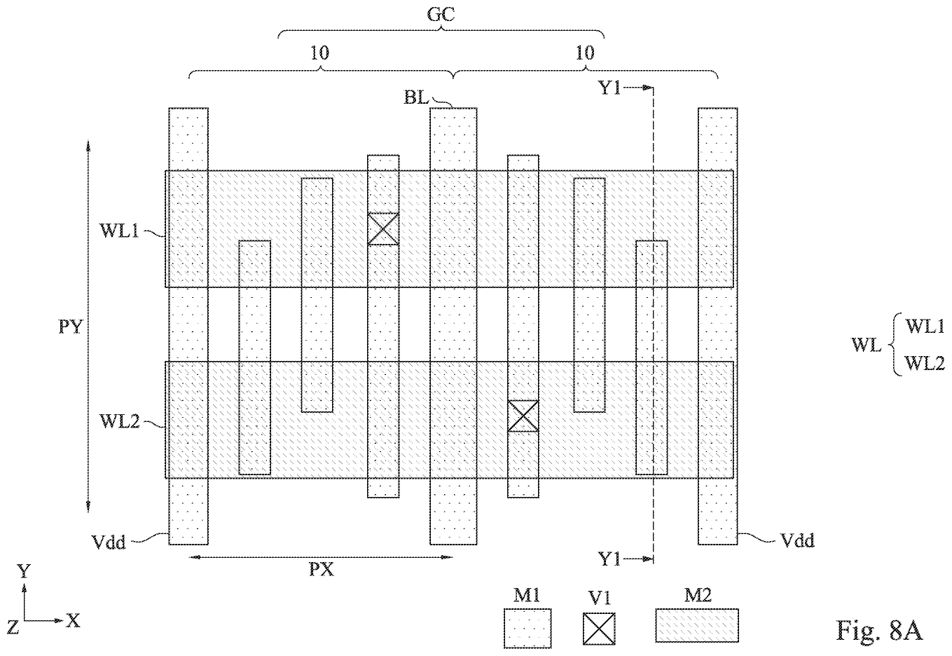

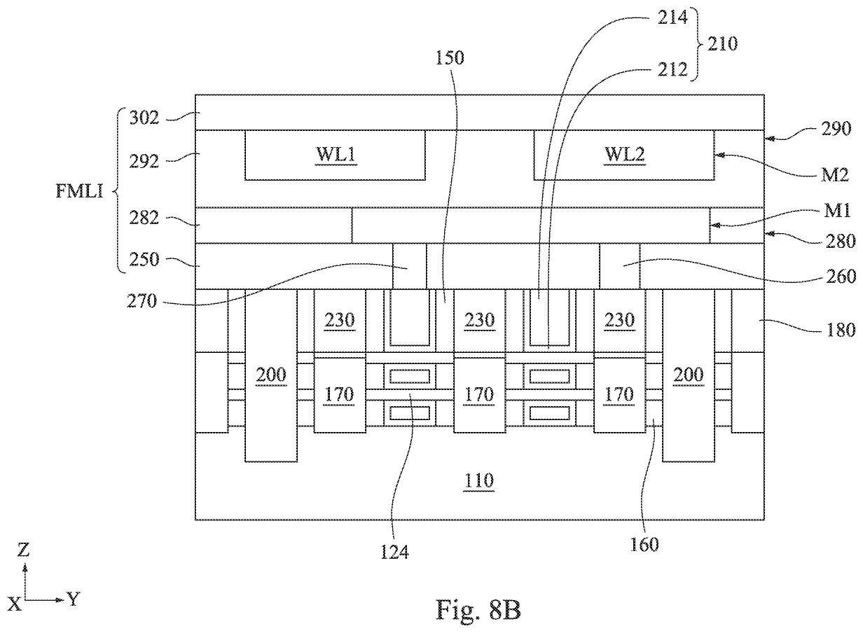

Reference is made to FIGS. 7A-7C and FIGS. 8A and 8B. A front-side multilayer interconnection (MLI) structure FMLI is formed over the substrate 110. The front-side MLI structure FMLI may include at least three front-side metallization layers. The number of front-side metallization layers may vary according to design specifications of the integrated circuit structure. Only two front-side metallization layers 280 and 290 are illustrated herein for the sake of simplicity. The front-side metallization layers each comprise one or more front-side inter-metal dielectric (IMD) layers, one or more horizontal interconnects respectively extending horizontally in the IMD layers, and one or more vertical interconnects respectively extending vertically in the IMD layers. For example, the front-side metallization layer 280/290 comprises IMD layers 282/292, horizontal interconnects (e.g., metal lines M1/M2) and vertical interconnects (e.g., metal via V1). The metal via V1 connects the metal lines M1 to the metal lines M2. In some embodiments, a routing direction of the metal lines M1 is different from or perpendicular to a routing direction of the metal lines M2. For example, the metal lines M2 extends along the direction X, and the metal line M1 extends along the direction Y.

The front-side metallization layers 280 may be referred to as a lowest metallization layer. The metal lines M1 of the lowest metallization layer 280 of the front-side MLI structure FMLI may include high power rails Vdd and bit lines BL. The high power rails Vdd may be electrically coupled to the positive power supply node CVdd, as shown in FIG. 1A. The metal lines M2 of the metallization layer 290 of the front-side MLI structure FMLI may include word lines WL. A power electrical connection can be established from the metal lines M1 (e.g., the high power rails Vdd) to the source/drain epitaxial structure 170. A signal electrical connection can be established from the metal lines M1 (e.g., the bit lines BL) to the source/drain epitaxial structure 170. A conductive path between source/drain epitaxial structure 170 and the high-k/metal gate structure 210 can be established by some metal lines M1.

The metallization layers M1 and M2 can be formed using, for example, a single damascene process, a dual damascene process, the like, or combinations thereof. In some embodiments, the IMD layers 282, 292, 302 may include low-k dielectric materials having k values, for example, lower than about 4.0 or even 2.0 disposed between such conductive features. In some embodiments, the IMD layers 282, 292, 302 may be made of, for example, phosphosilicate glass (PSG), borophosphosilicate glass (BPSG), fluorosilicate glass (FSG), SiOₓC_{y}, Spin-On-Glass, Spin-On-Polymers, silicon oxide, silicon oxynitride, combinations thereof, or the like, formed by any suitable method, such as spin-on coating, chemical vapor deposition (CVD), plasma-enhanced CVD (PECVD), or the like. The front-side metal lines and vias M1, M2, and V1 may comprise metal materials such as W, Ru, Co, Cu, Ti, TIN, Ta, TaN, Mo, Ni, combinations thereof, or the like. In some embodiments, the front-side metal lines and vias M1, M2, and V1 may further comprise one or more barrier/adhesion layers (not shown) to protect the respective front-side IMD layers 282 and 292 from metal diffusion (e.g., copper diffusion) and metallic poisoning. The one or more barrier/adhesion layers may comprise titanium, titanium nitride, tantalum, tantalum nitride, or the like, and may be formed using physical vapor deposition (PVD), CVD, ALD, or the like.

Reference is made to FIGS. 9A-9D. Back-side source/drain contacts 320 are formed over back sides of source/drain epitaxial structures 170. One or more processes are performed to remove materials at the back sides of source/drain epitaxial structures 170, thereby exposing the back sides of source/drain epitaxial structures 170. For example, a planarization process (e.g., a CMP process, or a grinding process) is performed to thinning down the substrate 110 (referring to FIGS. 8A and 8B). The planarization process may also remove portions of or all the isolation structures 130 (referring to FIG. 7C). In some embodiments, after the planarization process, one or more etching process may be performed to remove the substrate 110 and the isolation structures 130 (referring to FIGS. 7C, 8A, and 8B). In some alternative embodiments, portions of the isolation structures 130 (referring to FIG. 7C) may remain at back sides of the devices.

A back-side dielectric layer 310 is deposited over the back sides of the devices, e.g., the back sides of the source/drain epitaxial structures 170 and the back sides of the high-k/metal gate structures 210. In some embodiments, the back-side dielectric layer 310 may include, for example, a low-k dielectric material (with dielectric constant lower than about 7) such as SiO₂, SiN, SiCN, SiOC, SiOCN, the like, or combinations thereof. In some embodiments, the back-side dielectric layer 310 includes a high-k dielectric material such as HfO₂, ZrO₂, HfAlOₓ, HfSiOₓ and Al₂O₃, the like or combinations thereof. A CMP process is may be performed on the back-side dielectric layer 310.

Source/drain contacts 320 are formed over the back sides of the source/drain epitaxial structures 170. In some embodiments, the formation of the source/drain contacts 320 includes etching source/drain contact openings through the back-side dielectric layer 310 to expose back sides of the source/drain epitaxial structures 170, and depositing one or more metal materials into the source/drain contact openings. The metal materials may include W, Ru, Co, Cu, Ti, TiN, Ta, TaN, Mo, Ni, the like or combinations thereof. The metal materials are deposited to fill the source/drain contact openings by using suitable deposition techniques (e.g., CVD, PVD, ALD, the like or combinations thereof). Subsequently, a CMP process can be performed to remove excess metal materials outside the source/drain contact openings, while leaving metal materials in the source/drain contact openings to serve as the source/drain contacts 320. In some embodiments, prior to depositing the metal materials, metal silicide regions may be formed on exposed back sides of the source/drain epitaxial structures 170 by using a silicidation process.

Reference is made to FIGS. 9A-9D and FIGS. 10A and 10B. A ack-side multilayer interconnection (MLI) structure BMLI is formed over the substrate 110.

The back-side MLI structure BMLI may include plural back-side metallization layers. The number of back-side metallization layers may vary according to design specifications of the integrated circuit structure. Only two back-side metallization layers (e.g., the metallization layers 330 and 340) are illustrated for the sake of simplicity. The back-side metallization layers each comprise one or more back-side inter-metal dielectric (IMD) layers, one or more horizontal interconnects respectively extending horizontally in the IMD layers, and one or more vertical interconnects respectively extending vertically in the IMD layers. For example, the back-side metallization layer 330/340 comprises IMD layers 332/342, horizontal interconnects (e.g., metal lines BM1/BM2) and vertical interconnects (e.g., metal via BV1). The metal via BV1 may connect the metal lines BM1 to the metal lines BM2. In some embodiments, a routing direction of the metal lines BM1 is different from or perpendicular to a routing direction of the metal lines BM2. For example, the metal lines BM2 extends along the direction X, and the metal line BM1 extends along the direction Y.

The metal lines BM1 of the metallization layer 330 may include low power rails Vss1 and bit line bars BLB. In some embodiments, the bit line bars BLB may vertically overlap the bit lines BL. In some embodiments, the low power rails Vss1 may vertically overlap the high power rails Vdd. The low power rails Vss1 may be partially landed on the source/drain contacts 320. The metal lines BM2 of the metallization layer 340 may include a bus low power rail Vss2. The bus low power rail Vss2 can be electrically coupled to a power supply voltage node CVss as shown in FIG. 1A. A power electrical connection can be established from the metal lines BM1 and BM2 (e.g., the high power rails Vss1 and Vss2) to the source/drain epitaxial structure 170, for example, through the source/drain contacts 320. A signal electrical connection can be established from the metal lines BM1 (e.g., the bit line bars BLB) to the source/drain epitaxial structure 170, for example, through the source/drain contacts 320. The source/drain epitaxial structure 170 may be referred to as source/drain regions of the OD lines uncovered by the gate structures in the various layouts.

The metallization layers 330 and 340 can be formed using, for example, a single damascene process, a dual damascene process, the like, or combinations thereof. In some embodiments, the IMD layers 332 and 342 may include low-k dielectric materials having k values, for example, lower than about 4.0 or even 2.0 disposed between such conductive features. In some embodiments, the IMD layers 332 and 342 may be made of, for example, phosphosilicate glass (PSG), borophosphosilicate glass (BPSG), fluorosilicate glass (FSG), SiOₓC_{y}, Spin-On-Glass, Spin-On-Polymers, silicon oxide, silicon oxynitride, combinations thereof, or the like, formed by any suitable method, such as spin-on coating, chemical vapor deposition (CVD), plasma-enhanced CVD (PECVD), or the like. The back-side metal lines and vias BM1, BM2, and BV1 may comprise metal materials such as W, Ru, Co, Cu, Ti, TIN, Ta, TaN, Mo, Ni, combinations thereof, or the like. In some embodiments, the back-side metal lines and vias BM1, BM2, and BV1 may further comprise one or more barrier/adhesion layers (not shown) to protect the respective back-side IMD layers 332 and 342 from metal diffusion (e.g., copper diffusion) and metallic poisoning. The one or more barrier/adhesion layers may comprise titanium, titanium nitride, tantalum, tantalum nitride, or the like, and may be formed using physical vapor deposition (PVD), CVD, ALD, or the like.

As shown in the front-side layout of FIG. 7A and the back-side layout of FIG. 9A, the standard cell 10 is formed as a SRAM cell. For example, the n-type device PD1 and the p-type device PU1 share a continuous gate structure 210, the n-type device PD2 and the p-type device PU2 share a continuous gate structure 210. For power routing, nodes of the p-type devices PU1 and PU2 are electrically connected to the front-side power rails Vdd, nodes of the n-type devices PD1 and PD2 are electrically connected to the back-side power rails Vss1. For signal routing, a node of the n-type device PG1 is electrically connected to the front-side bit line BL, and a node of the n-type device PG2 is electrically connected to the back-side bit line bar BLB.

In some embodiments, as shown in the front-side layout of FIG. 7A and the back-side layout of FIG. 9A, the SRAM cell 10 has a tall cell structure. For example, the SRAM 10 has a pitch Px in the direction X and a pitch Py in the direction Y, and the pitch Px is shorted than the pitch Py for arranging two active regions and four gate lines into one cell 10. For example, the pitch Py is about 4 times the pitch between two adjacent gate lines. The pitch Px may correspond to a width of word lines WL. The pitch Py may correspond to a width of bit lines BL and bit line bars BLB. In some embodiments, a dimension ration of the pitch Py and the pitch Px may be in a range from about 1.2 to about 2.5. Two adjacent tall SRAM cells 10 may share a pair of the bit line BL and the bit line bar BLB. The tall SRAM cell structure used less OD lines (lower down to 2 groups) and first metal line metal tracks (lower down to 4) to finish cell connections, thereby achieving highly capability for cell scaling.

In some embodiments of the present embodiments, for benefiting the metal conductor RC performance, two adjacent cells 10 may share one front-side bit line BL and one back-side bit line bar BLB. In some alternative embodiments, the two adjacent cells 10 may share one front-side bit line bar BLB and one back-side bit line BL.

In some embodiments, all the bit lines BL are of the front-side MLI structure FMLI, and all the bit line bars BLB are of the back-side MLI structure BMLI In some other embodiments, all the bit line bars BLB are of the front-side MLI structure FMLI, and all the bit lines BL are of the back-side MLI structure BMLI. In some other embodiments, while each of groups of two adjacent cells 10 may share one bit line BL and one bit line bar BLB that are respectively of the front-side MLI structure FMLI and back-side MLI structure BMLI, some bit lines BL and some bit line bars BLB are of the front-side MLI structure FMLI, and the other bit lines BL and the other bit line bars BLB are of the back-side MLI structure BMLI.

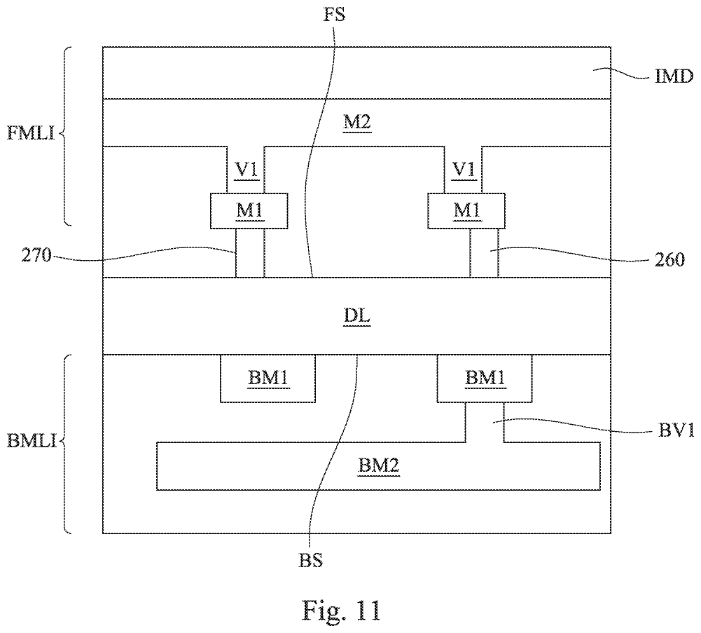

FIG. 11 is a cross-sectional views of an integrated circuit chip according to some embodiments of the present disclosure. The devices PG1, PG2, PU1, PU2, PD1, and PD2 in FIGS. 7A and 9A are illustrated as the device layer DL in FIG. 11. The front-side interconnect structure FMLI and the back-side interconnect structure BMLI are respectively at a front side FS of the device layer DL and at a back side BS of the device layer DL. The front-side interconnect structure FMLI is connected to the device layer DL through the via layer (e.g., source drain vias 260 and gate vias 270). In some embodiments of the present disclosure, for the signal routing, one of the front-side interconnect structure FMLI and the back-side interconnect structure BMLI comprises one of the bit line BL and the bit line bar BLB (referring to FIGS. 1A and 1B), while another one of the front-side interconnect structure FMLI and the back-side interconnect structure BMLI comprises another one of the bit line BL and the bit line bar BLB (referring to FIGS. 1A and 1B).

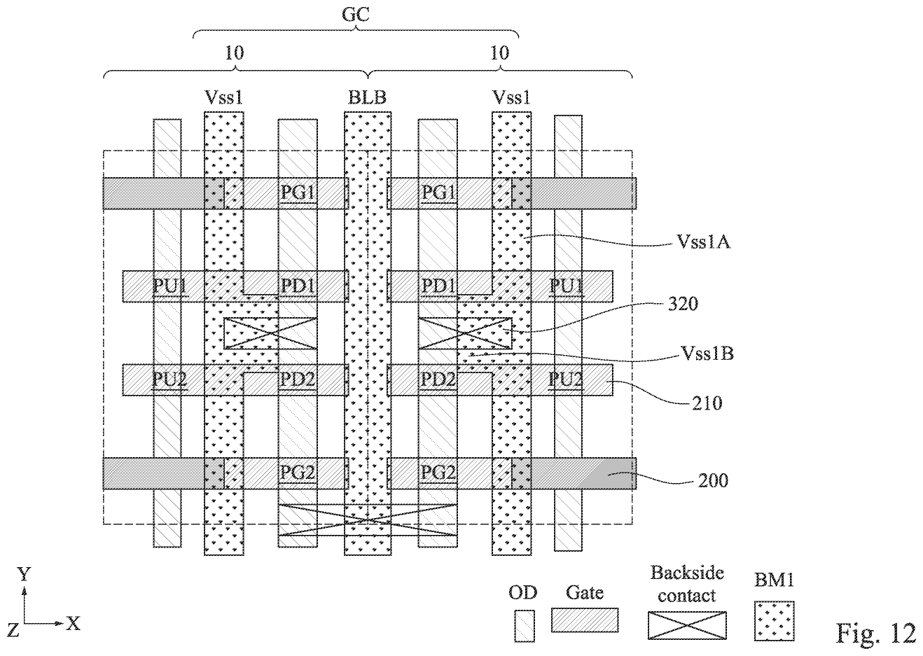

FIG. 12 illustrates a layout of an integrated circuit structure according to some embodiments of the present disclosure. Details of the present embodiment are similar to those illustrated in FIGS. 2-10B, except that the backside power rails Vss1 have a jop shape and partially landed on the source/drain contacts 320 connected to the devices PD1 and PD2. For example, the backside power rails Vss1 has a main line Vss1A and an extending portion Vss1B extending from on a side of the main line Vss1A adjacent the source/drain contacts 320 connected to the devices PD1 and PD2. A length of the extending portion Vss1B along the direction Y may be greater than a length of the source/drain contacts 320 along the direction Y. The configuration of the jog shape of the backside power rails Vss1 is beneficial for landing margin improvement as well as the contact resistance (Rc) (to the back-side metal line BM1) reduction. Other details of the present embodiments are similar to those illustrated above, not repeated herein.

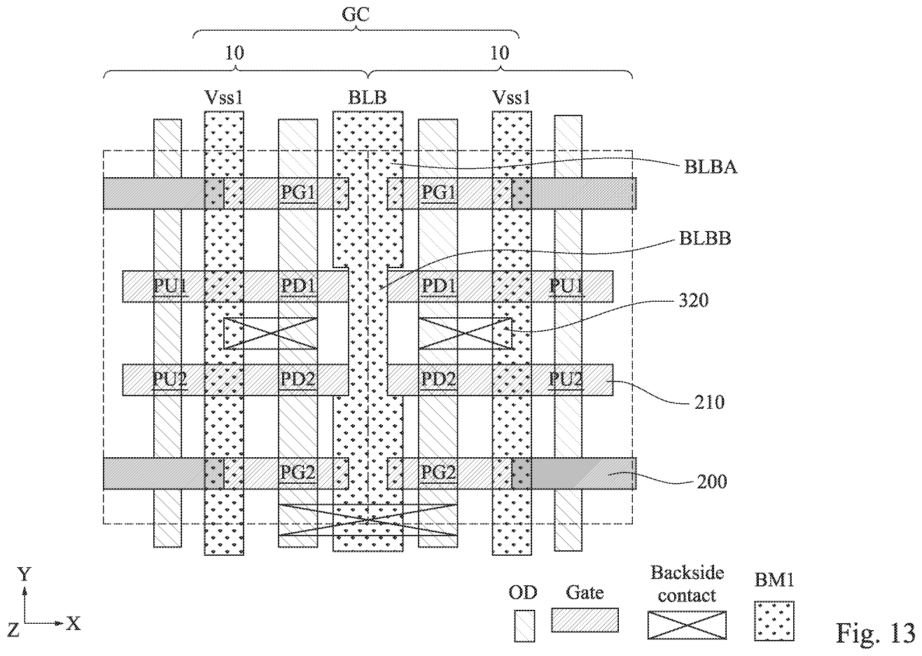

FIG. 13 illustrates a layout of an integrated circuit structure according to some embodiments of the present disclosure. Details of the present embodiment are similar to those illustrated in FIGS. 2-10B, except that the bit line bar BLB has a neck shape and partially landed on the source/drain contacts 320 connected to the devices PG2. For example, the bit line bar BLB has a wide line portion BLBA over the source/drain contacts 320 connected to the devices PG2 and a thin line portion BLBB between the source/drain contacts 320 connected to the devices PD1 and PD2. A width of the wide line portion BLBA may be greater than a width of the thin line portion BLBB. The configuration of the neck shape of the bit line bar BLB is beneficial for isolation margin improvement. Other details of the present embodiments are similar to those illustrated above, not repeated herein.

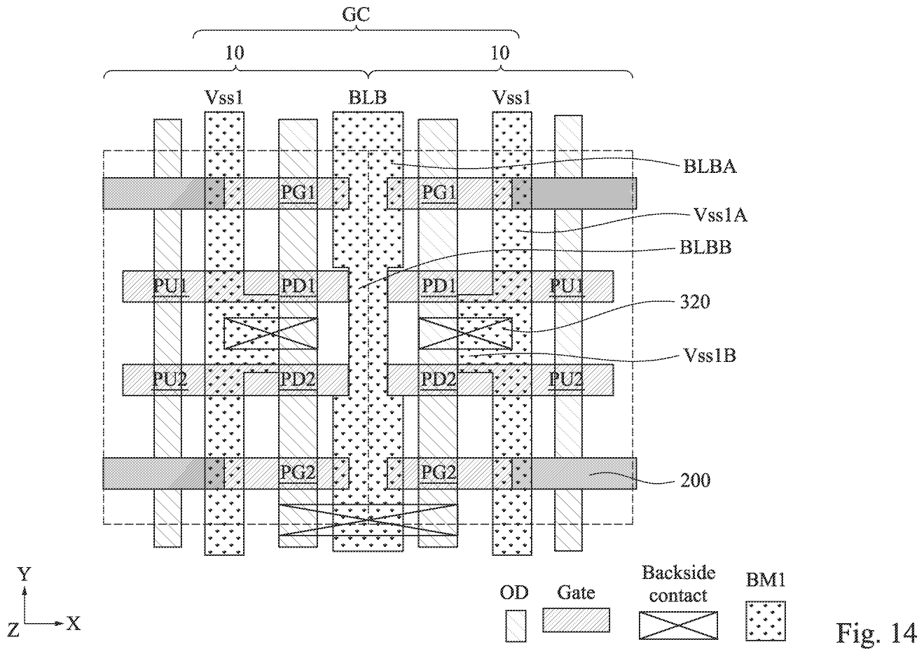

FIG. 14 illustrates a layout of an integrated circuit structure according to some embodiments of the present disclosure. Details of the present embodiment are similar to those illustrated in FIGS. 12 and 13, except that the backside power rails Vss1 has a jop shape and partially landed on the source/drain contacts 320 connected to the devices PD1 and PD2, and the bit line bar BLB has a neck shape and partially landed on the source/drain contacts 320. Other details of the present embodiments are similar to those illustrated above, not repeated herein.

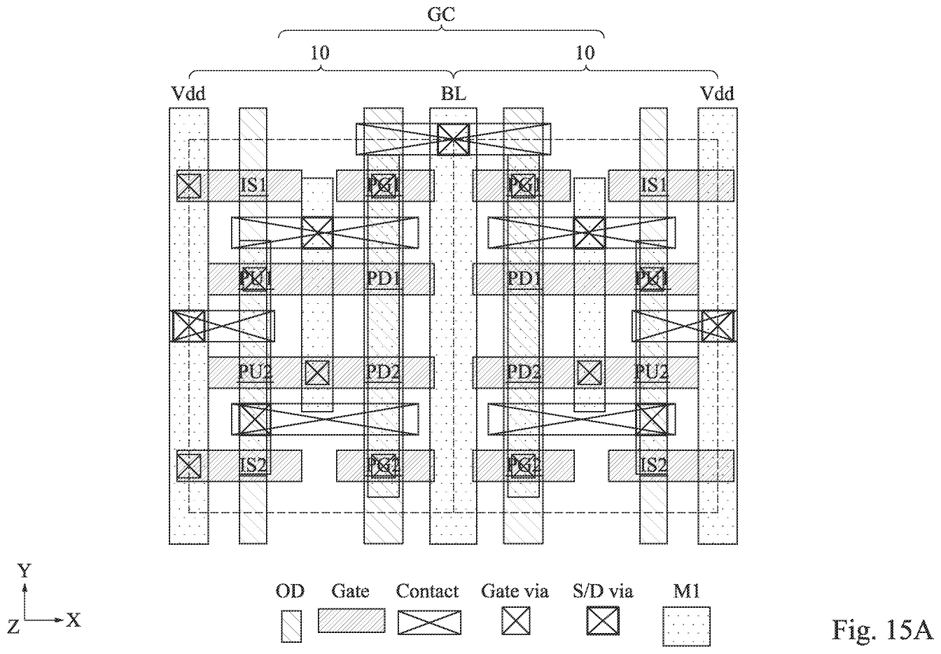

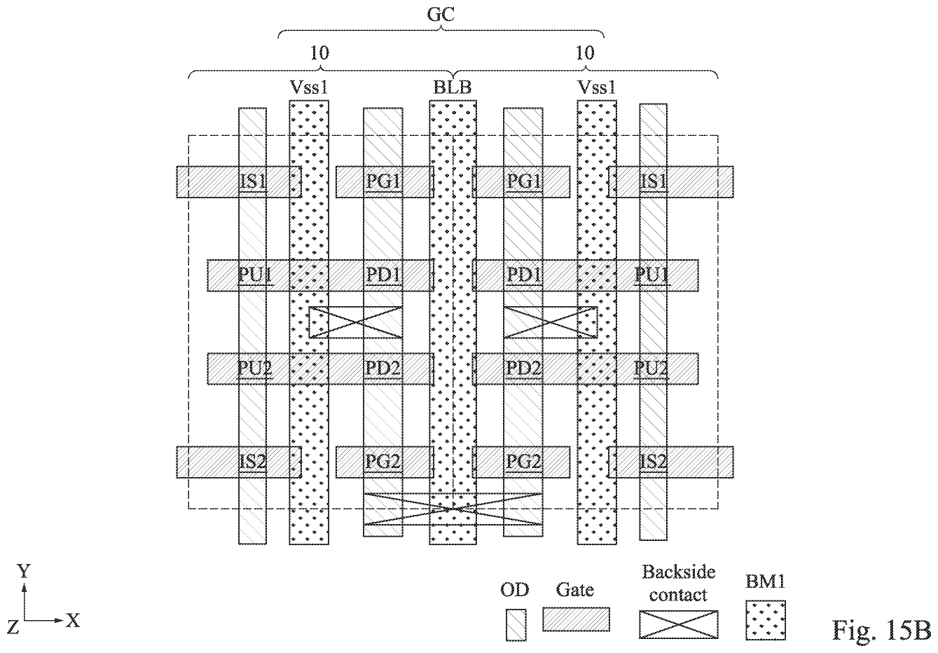

FIGS. 15A and 15B illustrate front-side and back-side layouts of an integrated circuit structure according to some embodiments of the present disclosure. Details of the present embodiment are similar to those illustrated in FIGS. 2-10B, except that the isolation features (dielectric gates) 200 are omitted. Instead, gate end dielectric 220 may be formed to cut the gate structures 210. As result, dummy devices IS1 and IS2 that are electrically disconnected from elements of the SRAM cells 10 are formed. Other details of the present embodiments are similar to those illustrated above, not repeated herein.

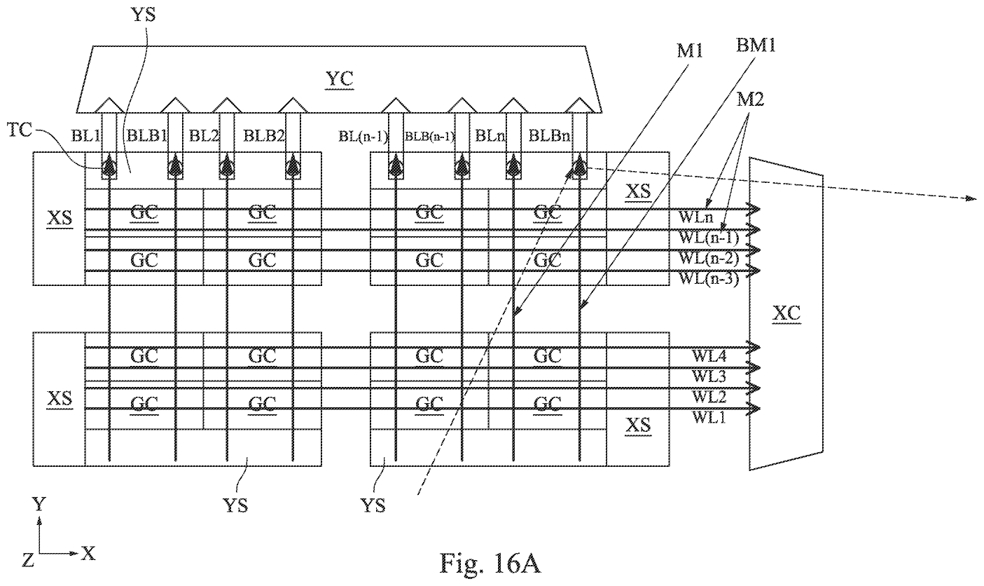

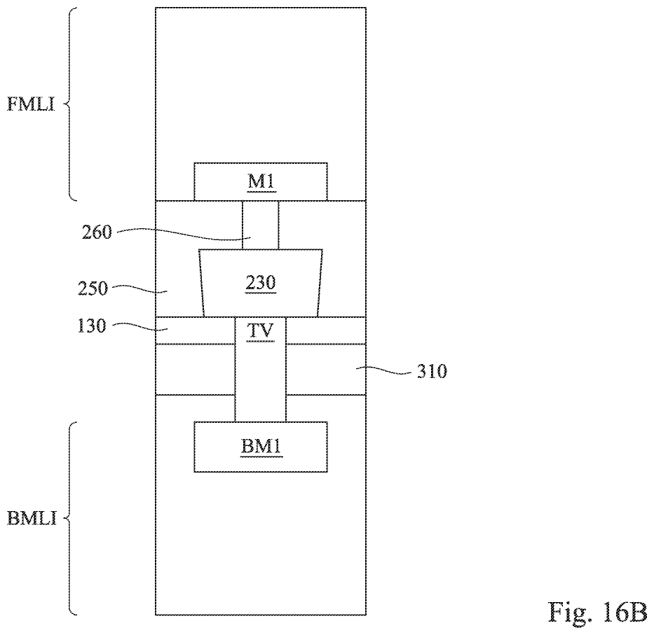

FIG. 16A illustrates a block diagram of an integrated circuit structure according to some embodiments of the present disclosure. FIG. 16B is a cross-sectional view of a tap structure of the integrated circuit chip of FIG. 16A. The SRAM array includes groups GC of SRAM cell. Bit lines BL1-BLn and bit line bars BLB1-BLBn may be electrically coupled between the groups GC of SRAM cell and a column circuit YC. Word lines WL1-WLn may be electrically coupled between the groups GC of SRAM cell and a row circuit XC. The column circuit YC may include write drivers, multiplexers, sense amplifier, the like, or the combination thereof. Plural tap cells TC may be formed at row edge regions XC and column edge regions YS of the SRAM array. Each of the tap cells TC may include a tap structure for routing front-side metal lines and back-side metal lines. For example, in the column edge regions YS, the tap structure includes a tap via TV, an elongated contact 230, and a via 260 to make an electrically connection between a front-side metal line M1 and a back-side metal line BM1, thereby routing the bit line bar BLB from the front-side metal line M1 to the backside back-side metal line BM1. The tap via TV may extend through the isolation structures 130 and the back-side dielectric layer 310.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that parts of metal layers are move to wafer back-side to reduce the routing loading as well as cell size further reduction. The less metal tracks in same area (layer) also benefits the metal conductor RC performance to achieve both lower resistance (wider width) and lower capacitance (larger space). Another advantage is that moving part of bit-lines to devices back-side can minimize the middle-end-of line (MEOL) capacitance between contact to gate due to it can reduce the overlay area between contact and gate, and also have lowest BEOL resistance and capacitance C from wider metal width and space, in which the bit-line capacitance is affected by metal-BL (BEOL), contact to gate (MEOL: CCO) and S/D to gate (FEOL). Still another advantage is that the word line routing and pass gate devices strap are setting to have grouping horizontal cells to mimic two rows. Still another advantage is that the merged two cells with one BL-pair to let BL has more room to implement either wider BL width for larger array (more columns and rows) implementation, or large metal space for capacitance reduction, or even achieve both advantages. Still another advantage is that in cell X-pitch direction, the single-port cell structure used less OD lines (lower down to 2 groups) and M1 metal tracks (lower down to 4) to finish key cell connections (CVdd, CVss, local connection and all landing lines) and therefore have highly capability for cell scaling. Still another advantage is that backside bit-line conductor may have a necking shape located adjacent the backside contact layer for isolation margin improvement. Still another advantage is that backside 1^{st} level Vss conductor has an extension jog shape to landed on backside Vss contact for landing margin improvement as well as Rc (BM1 to contact resistance) reduction.

In some embodiments of the present disclosure, an integrated circuit (IC) structure includes a device layer, a first word line, a second word line, a first bit line, and a second bit line. The device layer includes first and second static random access memory (SRAM) cells arranged along a first direction in a top view. The first and second word lines extend along the first direction and respectively electrically coupled to the first and second SRAM cells. The first bit line is over a frontside of the device layer. The first bit line extends along a second direction and electrically coupled to the first and second SRAM cells. The second direction is different from the first direction in the top view. The second bit line is over a backside of the device layer. The second bit line extend along the second direction and electrically coupled to the first and second SRAM cells.

In some embodiments of the present disclosure, an integrated circuit (IC) structure includes a first static random access memory (SRAM) cell and a second SRAM cell; a front-side contact over a frontside of a source/drain of a first transistor of the first SRAM cell and a frontside of a source/drain of a first transistor of the second SRAM cell; a front-side interconnection structure comprising a first bit line electrically coupled to the front-side contact; a first back-side contact over a backside of a source/drain of a second transistor of the first SRAM cell and a backside of a source/drain of a second transistor of the second SRAM cell; and a back-side interconnection structure comprising a second bit line electrically coupled to the back-side contact.

In some embodiments of the present disclosure, a method includes forming a device layer comprising a first static random access memory (SRAM) cell and a second SRAM arranged along a first direction in a top view; forming a front-side interconnection structure over a frontside of the device layer, wherein the front-side interconnection structure comprises: a first word line and a second word line extending along the first direction and respectively coupled to the first and second SRAM cell; and a first bit line extending along a second direction different from the first direction and electrically coupled to the first and second SRAM cells; and forming a back-side interconnection structure over a backside of the device layer, wherein the back-side interconnection structure comprises a second bit line extending along the second direction and electrically coupled to the first and second SRAM cells.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) structure, comprising:
a device layer comprising a first static random access memory (SRAM) cell and a second SRAM cell arranged along a first direction in a top view;
a first word line extending along the first direction and electrically coupled to the first SRAM cell;
a second word line extending along the first direction and electrically coupled to the second SRAM cell;
a first bit line over a frontside of the device layer, wherein the first bit line extends along a second direction and electrically coupled to the first and second SRAM cells, and the second direction is different from the first direction in the top view; and
a second bit line over a backside of the device layer, wherein the second bit line extends along the second direction and electrically coupled to the first and second SRAM cells.

2. The IC structure of claim 1, wherein the first bit line vertically overlaps the second bit line.

3. The IC structure of claim 1, wherein the first and second word lines are over the frontside of the device layer.

4. The IC structure of claim 1, further comprising:
a third word line extending along the first direction; and
a fourth word line extending along the first direction, wherein the device layer further comprises a third SRAM cell and a fourth SRAM cell, the third and fourth SRAM cells are respectively electrically coupled to the third and fourth word lines, and each of the third and fourth SRAMs cells is electrically coupled to the first bit line and the second bit line.

5. The IC structure of claim 1, further comprising:
a third bit line extending along the second direction; and
a fourth bit line extending along the second direction, wherein the device layer further comprises a fifth SRAM cell and a sixth SRAM cell, the fifth and sixth SRAM cells are respectively electrically coupled to the first and second word lines, and each of the fifth and sixth SRAM cells is electrically coupled to the third bit line and the fourth bit line.

6. The IC structure of claim 1, wherein a length of the first SRAM cell measured along the first direction is less than a length of the first SRAM cell measured along the second direction in the top view.

7. An integrated circuit (IC) structure, comprising:
a first static random access memory (SRAM) cell and a second SRAM cell;
a front-side contact over a frontside of a source/drain region of a first transistor of the first SRAM cell and a frontside of a source/drain region of a first transistor of the second SRAM cell;
a front-side interconnection structure comprising a first bit line electrically coupled to the front-side contact;
a first back-side contact over a backside of a source/drain region of a second transistor of the first SRAM cell and a backside of a source/drain region of a second transistor of the second SRAM cell; and
a back-side interconnection structure comprising a second bit line electrically coupled to the first back-side contact.

8. The IC structure of claim 7, wherein the first transistors of the first and second SRAM cells are first pass-gate transistors, and the second transistors of the first and second SRAM cells are second pass-gate transistors.

9. The IC structure of claim 7, wherein the first bit line vertically overlaps the second bit line.

10. The IC structure of claim 7, wherein the second bit line has a first line portion and a second line portion wider than the first line portion, and the second line portion of the second bit line vertically overlaps the first back-side contact.

11. The IC structure of claim 7, wherein the back-side interconnection structure further comprises:
a first power rail electrically coupled to a source/drain region of a third transistor of the first SRAM cell; and
a second power rail electrically coupled to a source/drain region of a third transistor of the second SRAM cell.

12. The IC structure of claim 11, further comprising:
a second back-side contact over a backside of the source/drain region of the third transistor of the first SRAM cell, wherein the first power rail is coupled to the second back-side contact, and the first power rail has a main line and an extending portion on a side of the main line, and the extending portion of the first power rail vertically overlaps the second back-side contact.

13. The IC structure of claim 11, wherein the second bit line, the first power rail, and the second power rail are of a same metallization layer of the back-side interconnection structure.

14. The IC structure of claim 11, wherein the second bit line is between the first power rail and the second power rail in a top view.

15. The IC structure of claim 7, further comprising:
a dummy transistor, wherein a gate structure of the dummy transistor is aligned with a gate structure of the first transistor of the first SRAM cell in a top view.

16. The IC structure of claim 7, further comprising:
an isolation structure in contact with and aligned with a gate structure of the first transistor of the first SRAM cell in a top view.

17. A method, comprising:
forming a first static random access memory (SRAM) cell and a second SRAM cell over a substrate, wherein the first and second SRAM cells are arranged along a first direction in a top view;
forming a front-side interconnection structure over a frontside of the substrate, wherein the front-side interconnection structure comprises:
a first word line and a second word line extending along the first direction and respectively coupled to the first and second SRAM cell; and
a first bit line extending along a second direction different from the first direction and electrically coupled to the first and second SRAM cells; and
forming a back-side interconnection structure over a backside of the substrate, wherein the back-side interconnection structure comprises a second bit line extending along the second direction and electrically coupled to the first and second SRAM cells.

18. The method of claim 17, further comprising:
prior to forming the front-side interconnection structure, forming a frontside contact over source/drain structures of first pass-gate transistors of the first and second SRAM cells.

19. The method of claim 17, further comprising:
prior to forming the back-side interconnection structure, forming a backside contact over source/drain structures of second pass-gate transistors of the first and second SRAM cells.

20. The method of claim 17, wherein the first bit line vertically overlaps the second bit line.
